(19) United States
(12) Patent Application Publication
(10) Pub. No.: US 2025/0351478 A1
(43) Pub. Date: Nov. 13, 2025

(54) HYBRID NANOSTRUCTURE SCHEME AND METHODS FOR FORMING THE SAME

(71) Applicant: Taiwan Semiconductor Manufacturing Company, Ltd., Hsin-Chu (TW)

(72) Inventors: Jung-Hung Chang, Changhua County (TW); Shih-Cheng Chen, Zhonghe Dist. (TW); Tsung-Han Chuang, Tainan City (TW); Wen-Ting Lan, Hsinchu City (TW); Chia-Cheng Tsai, Hsinchu (TW); Kuo-Cheng Chiang, Hsinchu County (TW); Chih-Hao Wang, Hsinchu County (TW)

(21) Appl. No.: 19/275,728

(22) Filed: Jul. 21, 2025

Related U.S. Application Data
(63) Continuation of application No. 18/404,226, filed on Jan. 4, 2024.
(60) Provisional application No. 63/583,105, filed on Sep. 15, 2023.
(60) Provisional application No. 63/610,280, filed on Dec. 14, 2023.

(51) Int. Cl. H10D 62/10; H10D 30/01; H10D 30/43; H10D 30/67; H10D 62/13; H10D 64/01; H10D 84/01; H10D 84/03; H10D 84/85

(52) U.S. Cl. CPC H10D 62/116; H10D 30/014; H10D 30/031; H10D 30/43; H10D 30/6757; H10D 62/151; H10D 64/018; H10D 84/017; H10D 84/038; H10D 84/85

(57) ABSTRACT

Semiconductor structures and methods of forming the same are provided. In an embodiment, an exemplary semiconductor structure includes a first transistor. The first transistor includes a first gate structure wrapping around a plurality of first nanostructures disposed over a substrate, a first source/drain feature electrically coupled to a topmost nanostructure of the plurality of first nanostructures and isolated from a bottommost nanostructure of the plurality of first nanostructures by a first dielectric layer, and a first semiconductor layer disposed between the substrate and the first source/drain feature, wherein the first source/drain feature is in direct contact with a top surface of the first semiconductor layer.

### PRIORITY DATA

The present application is a continuation application of U.S. patent application Ser. No. 18/404,226, filed Jan. 4, 2024, which claims the benefit of U.S. Provisional Patent Application No. 63/583,105, filed Sep. 15, 2023 and U.S. Provisional Patent Application No. 63/610,280, filed Dec. 14, 2023, each of which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures, and a GAA transistor may also be referred to as a nanostructure transistor. As semiconductor IC may generally include a variety of different device types with different performance requirements. As such, providing multi-gate devices (e.g., GAA transistors) that are able to meet such diverse device performance requirements remains a challenge. Thus, existing techniques have not proved entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary semiconductor structure to undergo various stages of operations in the method of FIG. 1, according to various aspects of the present disclosure.

FIGS. 3A, 4A, 5A, 6A, 7A, 8A, 9A, 10A, 11A, 12A, 13A, 14A, 15A, and 16A (FIGS. 3A-16A) illustrate fragmentary cross-sectional views of the semiconductor structure taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, 14B, 15B, and 16B (FIGS. 3B-16B) illustrate fragmentary cross-sectional views of the semiconductor structure taken along line B-B′ as shown in FIG. 2 during various fabrication stages in the method of FIG. 1, according to one or more aspects of the present disclosure.

FIGS. 3C, 4C, 5C, 6C, 7C, 8C, 9C, 10C, 11C, 12C, 13C, 14C, 15C, and 16C (FIGS. 3C-16C) illustrate fragmentary cross-sectional views of the semiconductor structure taken along line C-C′ as shown in FIG. 2 during various fabrication stages in the method of FIG. 1, according to one or more aspects of the present disclosure.

FIGS. 3D, 4D, 5D, 6D, 7D, 8D, 9D, 10D, 11D, 12D, 13D, 14D, 15D, and 16D (FIGS. 3D-16D) illustrate fragmentary cross-sectional views of the semiconductor structure taken along line D-D′ as shown in FIG. 2 during various fabrication stages in the method of FIG. 1, according to one or more aspects of the present disclosure.

FIGS. 3E, 4E, 11E, 14E, and 16E illustrate fragmentary cross-sectional views of the semiconductor structure taken along line E-E′ as shown in FIG. 2 during various fabrication stages in the method of FIG. 1, according to one or more aspects of the present disclosure.

FIGS. 3F, 4F, 11F, 14F, and 16F illustrate fragmentary cross-sectional views of the semiconductor structure taken along line F-F′ as shown in FIG. 2 during various fabrication stages in the method of FIG. 1, according to one or more aspects of the present disclosure.

FIGS. 3G, 4G, 11G, 14G, and 16G illustrate fragmentary cross-sectional views of the semiconductor structure taken along line G-G′ as shown in FIG. 2 during various fabrication stages in the method of FIG. 1, according to one or more aspects of the present disclosure.

FIGS. 3H, 4H, 11H, 14H, and 16H illustrate fragmentary cross-sectional views of the semiconductor structure taken along line H-H′ as shown in FIG. 2 during various fabrication stages in the method of FIG. 1, according to one or more aspects of the present disclosure.

FIG. 17 illustrates a flow chart of a first alternative method for forming a semiconductor structure, according to one or more aspects of the present disclosure.

FIGS. 18A, 19A, 20A, 21A, and 22A (FIGS. 18A-22A) illustrate fragmentary cross-sectional views of the semiconductor structure taken along line A-A′ as shown in FIG. 2 during various fabrication stages in the method of FIG. 17, according to one or more aspects of the present disclosure.

FIGS. 18B, 19B, 20B, 21B, and 22B (FIGS. 18B-22B) illustrate fragmentary cross-sectional views of the semiconductor structure taken along line B-B′ as shown in FIG. 2 during various fabrication stages in the method of FIG. 17, according to one or more aspects of the present disclosure.

FIGS. 18C, 19C, 20C, 21C, and 22C (FIGS. 18C-22C) illustrate fragmentary cross-sectional views of the semiconductor structure taken along line C-C′ as shown in FIG. 2 during various fabrication stages in the method of FIG. 17, according to one or more aspects of the present disclosure.

FIGS. 18D, 19D, 20D, 21D, and 22D (FIGS. 18D-22D) illustrate fragmentary cross-sectional views of the semiconductor structure taken along line D-D′ as shown in FIG. 2 during various fabrication stages in the first alternative method of FIG. 17, according to one or more aspects of the present disclosure.

FIGS. 23A, 23B, 23C, 23D illustrate alternative fragmentary cross-sectional views of the semiconductor structure taken along line A-A′, B-B′, C-C′, D-D′ as shown in FIG. 2 during various fabrication stages in the first alternative method of FIG. 17, respectively according to one or more aspects of the present disclosure.

FIGS. 24A, 24B, 24C, 24D, 24E, 24F, 24G, and 24H illustrate alternative fragmentary cross-sectional views of the semiconductor structure taken along line A-A′, B-B′, C-C′, D-D′, E-E′, F-F′, G-G′, and H-H′ as shown in FIG. 2 during various fabrication stages in the first alternative method of FIG. 17, respectively, according to one or more aspects of the present disclosure.

FIG. 25 illustrates a flow chart of a second alternative method for forming a semiconductor structure, according to one or more aspects of the present disclosure.

FIGS. 26A and 27A, 26B and 27B, 26C and 27C, 26D and 27D illustrate fragmentary cross-sectional views of the semiconductor structure taken along line A-A′, B-B′, C-C′, D-D′, as shown in FIG. 2 during various fabrication stages in the second alternative method of FIG. 25, respectively, according to one or more aspects of the present disclosure.

FIGS. 28A, 28B, 28C, 28D illustrate alternative fragmentary cross-sectional views of the semiconductor structure taken along line A-A′, B-B′, C-C′, D-D′, as shown in FIG. 2 during various fabrication stages in the second alternative method of FIG. 25, respectively, according to one or more aspects of the present disclosure.

FIGS. 29A, 29B, 29C, 29D, 29E, 29F, 29G, and 29H illustrate alternative fragmentary cross-sectional views of the semiconductor structure taken along line A-A′, B-B′, C-C′, D-D′, E-E′, F-F′, G-G′, and H-H′ as shown in FIG. 2 during various fabrication stages in the second alternative method of FIG. 25, respectively, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

GAA transistors have wide applications. In some implementations (e.g., low power consumption devices), GAA transistors may be designed to provide low leakage current to reduce power consumption, while in some other implementations (e.g., high performance devices), GAA transistors may be designed to have high drive current and high speed. Usually, transistors with a greater effective channel width (W_{eff}) tend to have higher performance in terms of switching speed and the on-state current. Transistors with a smaller effective channel width (W_{eff}) tend to have lower power consumption. For example, a logic hybrid cell may include both high performance transistors and low power transistors. Fabricating GAA transistors to meet different application requirements can involve complicated processes associated with high cost. In addition, forming p-type GAA transistors with satisfactory strain performance while providing a low leakage current remains a challenge.

The present disclosure provides a hybrid nanostructure scheme that can form a semiconductor structure having both high speed GAA transistors and low power GAA transistors by configuring different number of effective channel layers coupled to corresponding source/drain features. In an embodiment, a low power GAA transistor may have a fewer number of channel layers coupled to its corresponding n-type/p-type source/drain features; and a high-speed GAA transistor may have a greater number of channel layers coupled to its corresponding n-type/p-type source/drain features. The lower power GAA transistor includes a vertical sidewall dielectric layer providing an isolation between source/drain features and, for example, a bottommost channel layer in a channel region. By implementing this hybrid nanostructure scheme, GAA transistors with different electrical characterizations may be formed on a same substrate. In addition, forming this vertical sidewall dielectric layer to provide isolation can allow p-type source/drain features of p-type lower power GAA transistors to epitaxially grow from the bottom up and thus maintain satisfactory strain performance.

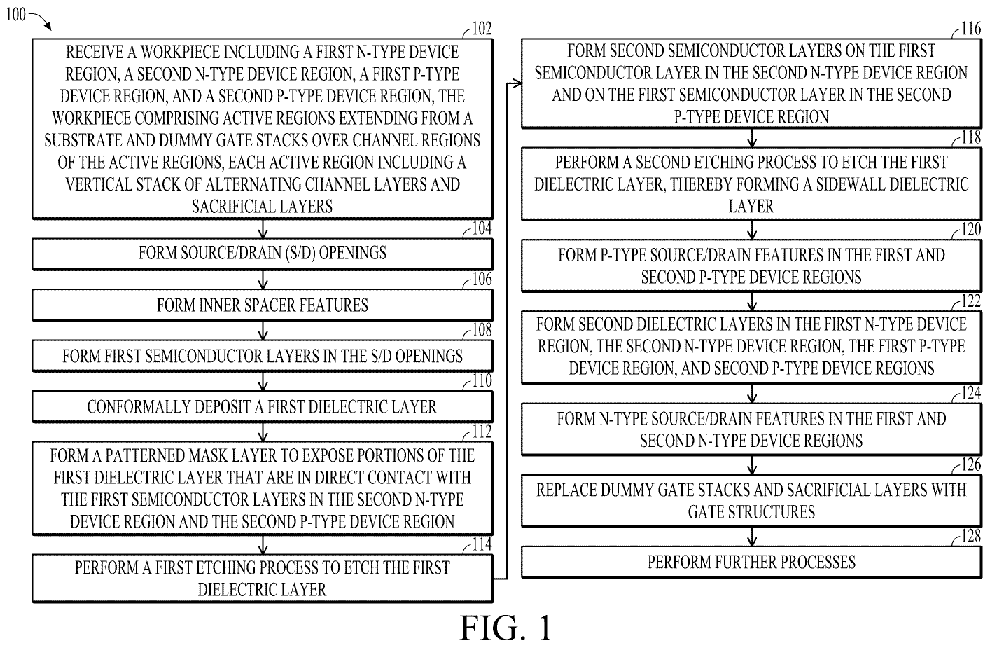

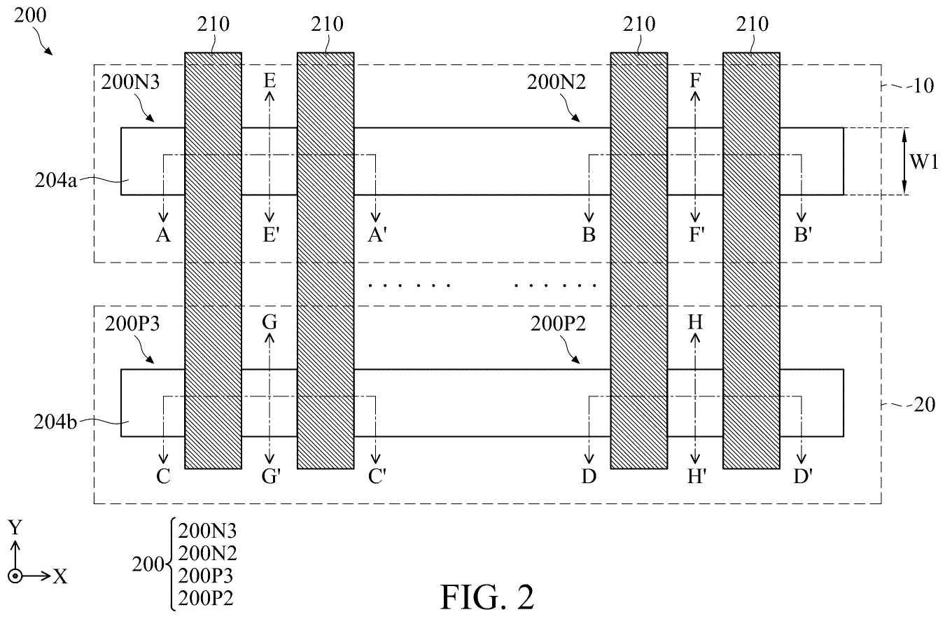

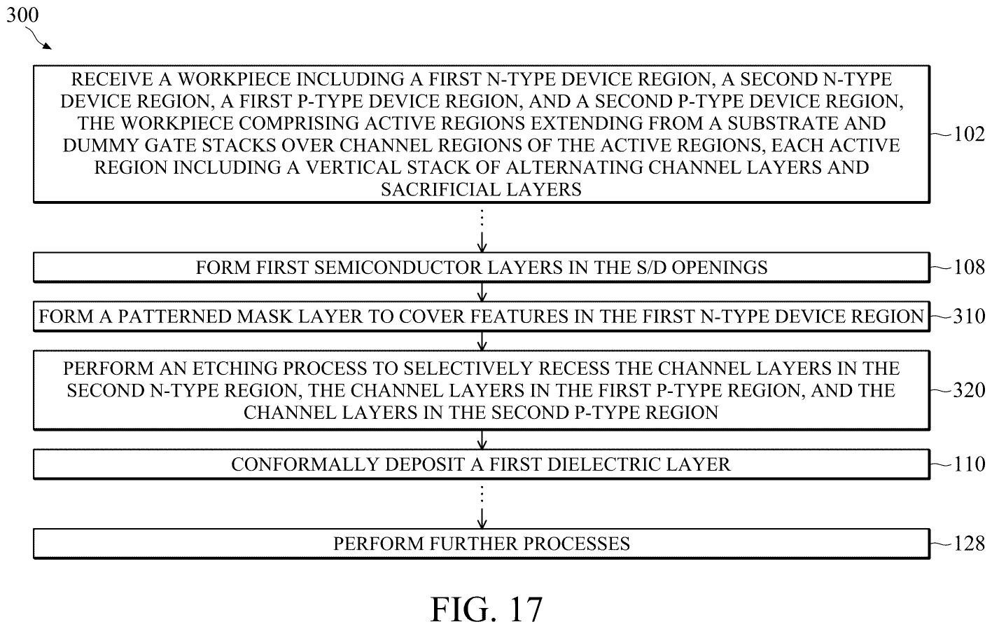

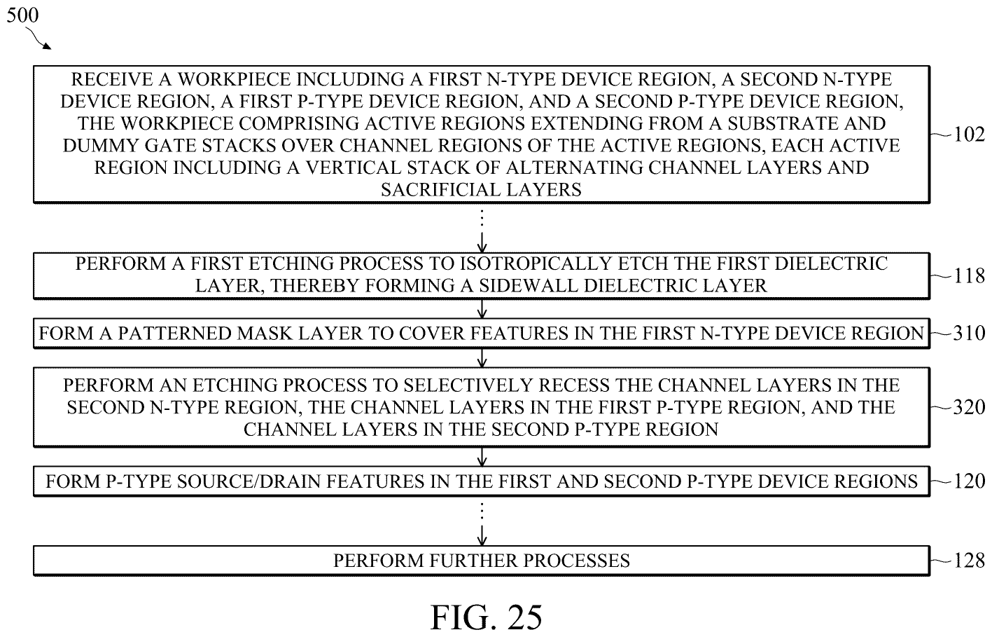

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2 and 3A-16H, which are fragmentary top/cross-sectional views of a semiconductor structure 200 at different stages of fabrication according to embodiments of method 100. FIG. 17 is a flowchart illustrating a method 300 of forming a semiconductor structure according to embodiments of the present disclosure. Method 300 is described below in conjunction with FIGS. 2 and 18A-24H, which are fragmentary top/cross-sectional views of a semiconductor structure 400/400′ at different stages of fabrication according to embodiments of method 300. FIG. 25 is a flowchart illustrating a method 500 of forming a semiconductor structure according to embodiments of the present disclosure. Method 500 is described below in conjunction with FIGS. 2 and 26A-29H, which are fragmentary top/cross-sectional views of a semiconductor structure 600/600′ at different stages of fabrication according to embodiments of method 500.

Method 100/300/500 is merely an example and is not intended to limit the present disclosure to what is explicitly illustrated therein. Additional steps may be provided before, during and after the method 100/300/500, and some steps described can be replaced, eliminated, or moved around for additional embodiments of the method. Not all steps are described herein in detail for reasons of simplicity. For avoidance of doubts, the X, Y and Z directions in FIGS. 2-16H, 18A-24H and 26A-29H are perpendicular to one another and are used consistently throughout the present disclosure. Throughout the present disclosure, like reference numerals denote like features unless otherwise excepted.

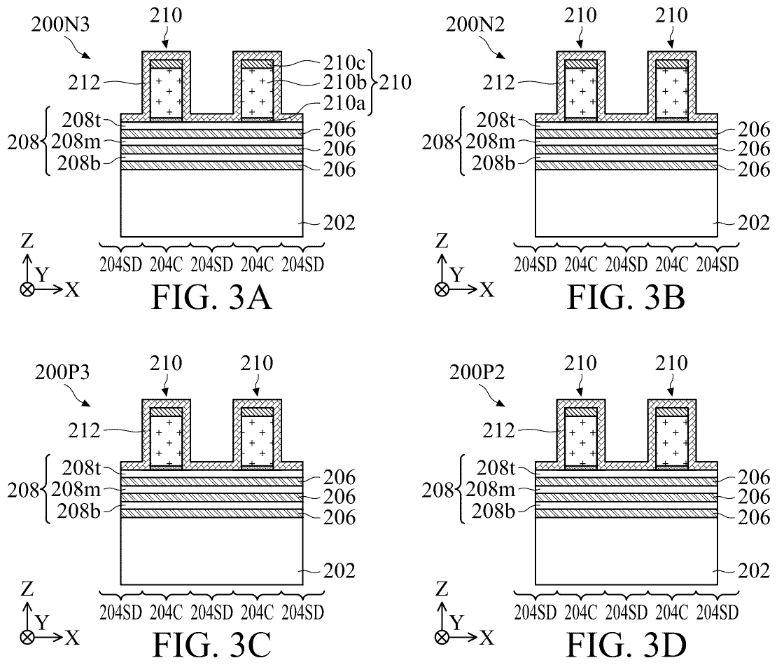

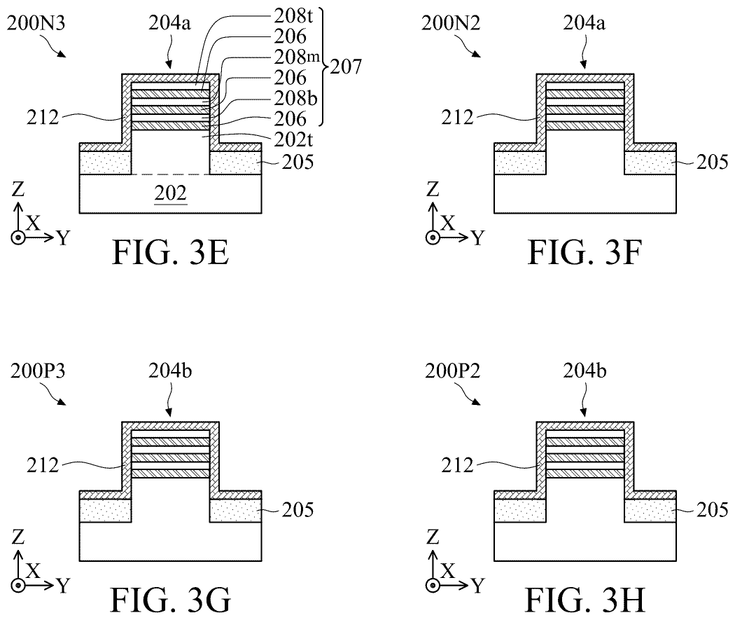

Referring to FIGS. 1, 2 and 3A-3H, method 100 includes a block 102 where a semiconductor structure 200 that includes a first region 10 and a second region 20 is received. FIG. 2 depicts a fragmentary top view of the semiconductor structure 200 to undergo various stages of operations in the method 100 of FIG. 1, according to various aspects of the present disclosure. FIGS. 3A, 3B, 3C, 3D, 3E, 3F, 3G, and 3H illustrates fragmentary cross-sectional views of the semiconductor structure 200 taken along line A-A′, B-B′, C-C′, D-D′, E-E′, F-F′, G-G′, and H-H′ as shown in FIG. 2, respectively.

As illustrated in FIGS. 3A-3H, the semiconductor structure 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); a non-semiconductor material, such as soda-lime glass, fused silica, fused quartz, and/or calcium fluoride (CaF2); and/or combinations thereof. In one embodiment, the substrate 202 is a silicon (Si) substrate. The substrate 202 may be uniform in composition or may include various layers, some of which may be selectively etched to form fin-shaped active regions (e.g., the fin-shaped active regions 204a-204b). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed in the substrate 202. In the embodiments represented in FIG. 2, a portion of the substrate 202 in the first region 10 is doped with an p-type dopant and may be referred to as a p-type well (not shown), and a portion of the substrate 202 in the second region 20 is doped with an n-type dopant and may be referred to as an n-type well (not shown). The p-type dopant may include boron (B), boron difluoride (BF₂), or indium (In). The n-type dopant may include phosphorus (P) or arsenic (As). The n-type well and the p-type well may be formed using ion implantation or thermal diffusion and may be considered portions of the substrate 202. As will be described further below, the first region 10 is an n-type field effect transistor (NFET) region for forming NFET(s) with different numbers of nanostructures and the second region 20 is a p-type field effect transistor (PFET) region for forming PFET(s) with different numbers of nanostructures. In the present disclosure, high speed n-type devices and high speed p-type devices will be formed in the first n-type device region 200N3 and the first p-type device region 200P3, respectively; low power n-type devices and low power p-type devices will be formed in the second n-type device region 200N2 and the second p-type device region 200P2, respectively. As will be described below, source/drain features of the GAA transistors formed in the second n-type device region 200N2/second p-type device region 200P2 will be coupled to a fewer number of channel layers (i.e., nanostructures) than that of the source/drain features of GAA transistors formed in the first n-type device region 200N3/first p-type device region 200P3.

Still referring to FIGS. 2 and 3A-3H, the semiconductor structure 200 includes a number of fin-shaped active regions (e.g., fin-shaped active regions 204a, 204b) protruding from the substrate 202. In the present embodiments, the first region 10 includes the fin-shaped active region 204a, and the second region 20 includes the fin-shaped active region 204b. The number of fin-shaped active regions depicted in FIG. 2 is just an example, the semiconductor structure 200 may include any suitable number of active regions. Each of the fin-shaped active regions 204a-204b may be formed from a top portion 202t (shown in FIG. 3A) of the substrate 202 and a vertical stack 207 (shown in FIG. 3E) of alternating semiconductor layers disposed on a top surface of the substrate 202. In an embodiment, the vertical stack 207 includes a number of channel layers (e.g., channel layers 208b, 208m, 208t) interleaved by a number of sacrificial layers 206. The channel layers 208b, 208m, 208t may be individually or collectively referred to as channel layer(s) 208. Each of the channel layers 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). Although the vertical stack 207 of the depicted example includes three channel layers 208b, 208m, 208t and three sacrificial layers 206, it is understood that the vertical stack 207 may include any suitable number (e.g., 2 to 10) of channel layers and any suitable number of sacrificial layers. The vertical stack 207 and the top portion 202t of the substrate 202 are then patterned to form the fin-shaped active regions 204a-204b. In some embodiments, the patterned top portion 202t of the substrate 202 may be referred to as a mesa structure 202t. Each of the fin-shaped active regions 204a-204b extends lengthwise along the X direction and is divided into channel regions 204C overlapped by dummy gate stacks 210 (to be described below) and source/drain regions 204SD not overlapped by the dummy gate stacks 210. Source/drain region(s) 204SD may refer to a source region or a drain region, individually or collectively dependent upon the context. Each of the channel regions 204C is disposed between two source/drain regions 204SD along the X direction. In an embodiment, each of the fin-shaped active regions 204a-204b has a uniform width (e.g., width W1).

The semiconductor structure 200 also includes isolation features 205 (shown in FIGS. 3E-3H) formed around the fin-shaped active regions 204a-204b to isolate one fin-shaped active region from an adjacent fin-shaped active region. The isolation features 205 may include shallow trench isolation (STI) features 205 and may include silicon oxide, silicon oxynitride, fluorine-doped silicate glass (FSG), a low-k dielectric, combinations thereof, and/or other suitable materials.

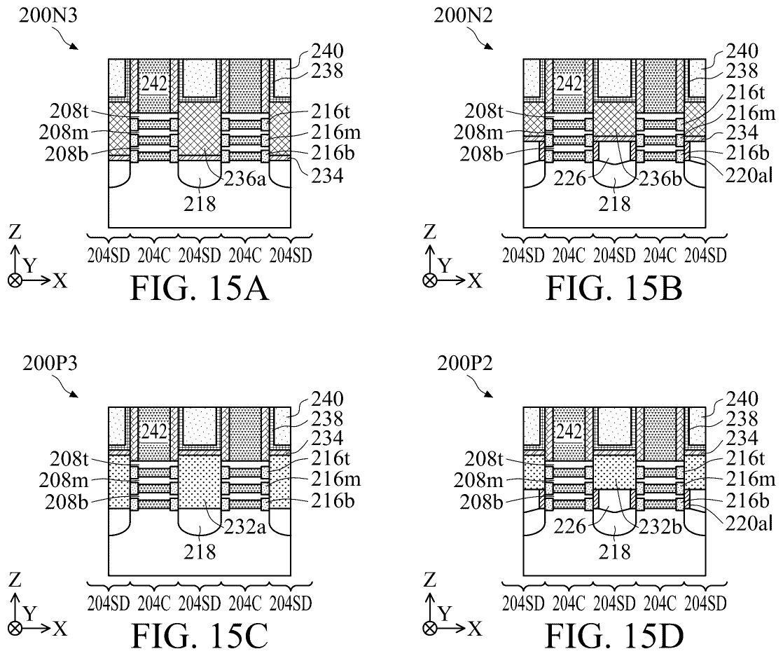

The semiconductor structure 200 also includes dummy gate stacks 210. Each of the dummy gate stacks 210 includes a dummy gate dielectric layer 210a, a dummy gate electrode layer 210b over the dummy gate dielectric layer 210a, a gate-top hard mask layer 210c over the dummy gate electrode layer 210b. The dummy gate dielectric layer 210a may include silicon oxide. The dummy gate electrode layer 210b may include polysilicon. The gate-top hard mask layer 210c may include silicon oxide, silicon nitride, and/or other suitable materials. Suitable deposition process, photolithography and etching process may be employed to form the dummy gate stacks 210. In this embodiment, a gate replacement process (or gate-last process) is adopted where the dummy gate stacks 210 serve as placeholders for functional gate structures (e.g., gate structures 242 shown in FIGS. 15A-15D). Other processes and configurations are possible. Four dummy gate stacks 210 are shown in FIG. 2, but the semiconductor structure 200 may include any suitable number of dummy gate stacks 210.

The semiconductor structure 200 also includes a gate spacer layer 212 over the substrate 202. The gate spacer layer 212 may be a single-layer structure or a multi-layer structure. In an example process, a first spacer layer (not separately labeled) is conformally deposited over the semiconductor structure 200 and a second spacer (not separately labeled) layer is conformally deposited over the first spacer layer. The first spacer layer and the second spacer layer may be conformally deposited over by atomic layer deposition (ALD), chemical vapor deposition (CVD), or any other suitable deposition process. The term “conformally” may be used herein for ease of description of a layer having substantially uniform thickness over various regions of the semiconductor structure 200. The first spacer layer may include silicon oxide, silicon nitride, silicon oxycarbide, silicon oxycarbonitride, silicon carbonitride, metal nitride, or other suitable dielectric materials. The second spacer layer may include silicon oxide, silicon nitride, silicon oxycarbide, silicon oxycarbonitride, silicon carbonitride, metal nitride, or other suitable dielectric materials. A composition of the first spacer layer is different from a composition of the second spacer layer. In an embodiment, the second spacer layer includes silicon nitride (SiN).

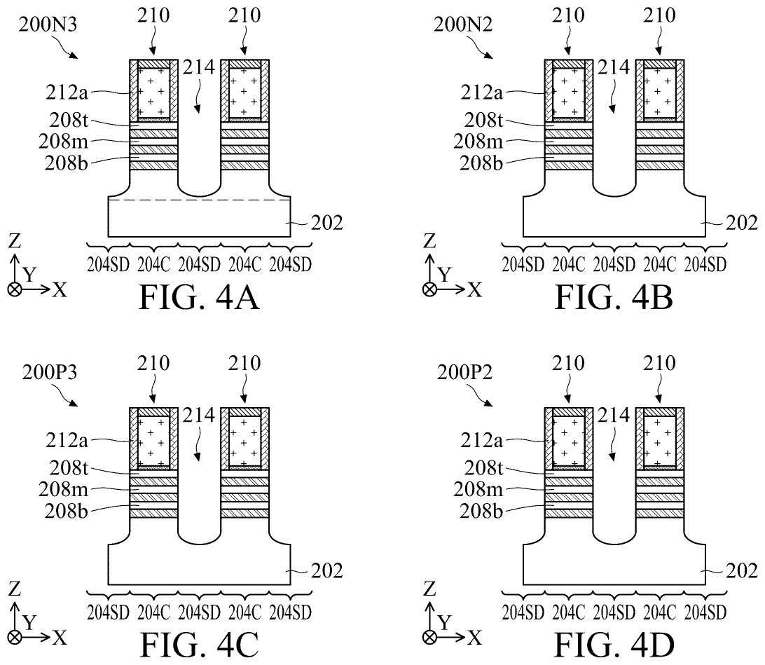

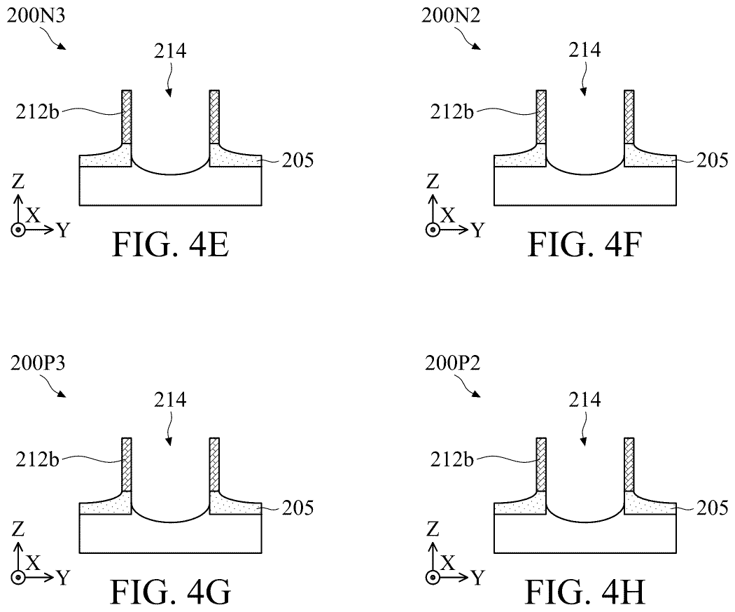

Referring to FIGS. 1 and 4A-4H, method 100 includes a block 104 where source/drain regions 204SD of the fin-shaped active regions 204a-204b are recessed to form source/drain openings 214. An etching process is performed to remove portions of the gate spacer layer 212 over top-facing surfaces of the semiconductor structure 200 to form gate spacers 212a extending along sidewalls of the dummy gate stacks 210 and fin sidewall spacers 212b (shown in FIGS. 4E-4H) extending along lower portions of sidewalls of the fin-shaped active regions 204a-204b.

In some embodiments, the source/drain regions 204SD of the fin-shaped active regions 204a-204b are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof. In the present embodiments, the source/drain openings 214 extend into the top portion 202t of the substrate 202.

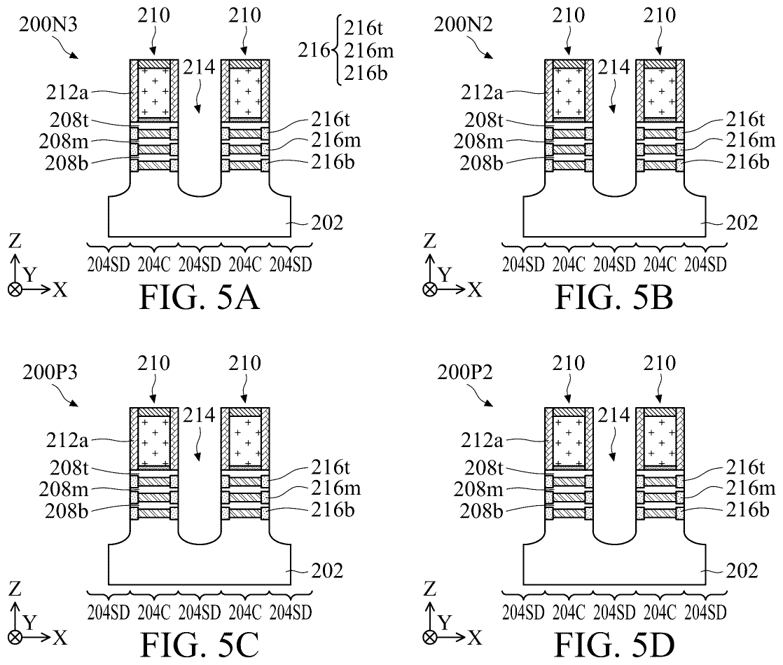

Referring to FIGS. 1 and 5A-5D, method 100 includes a block 106 where inner spacer features (e.g., inner spacer features 216b, 216m, 216t) are formed. After forming the source/drain openings 214, the sacrificial layers 206 exposed in the source/drain openings 214 are selectively and partially recessed to form inner spacer recesses (filled by inner spacer features), while the exposed channel layers 208 are substantially unetched. In some embodiments, this selective recess may include a selective isotropic etching process (e.g., a selective dry etching process or a selective wet etching process), and the extent at which the sacrificial layers 206 is recessed is controlled by duration of the etching process. After the formation of the inner spacer recesses, an inner spacer material layer is then conformally deposited using CVD or ALD over the semiconductor structure 200, including over and into the inner spacer recesses. The inner spacer material may include silicon nitride, silicon oxycarbonitride, silicon carbonitride, silicon oxide, silicon oxycarbide, silicon carbide, or silicon oxynitride. The inner spacer material layer is then etched back to form the inner spacer features (e.g., the inner spacer features 216b, 216m, and 216t), as illustrated in FIGS. 5A-5D. In some embodiments, a composition of the inner spacer material layer is different than a composition of the gate spacers 212a and the fin sidewall spacers 212b such that the etching back of the inner spacer material layer does not substantially etch the gate spacers 212a and the fin sidewall spacers 212b. In the illustrated embodiments, the bottommost inner spacer feature 216b is disposed between the substrate 202 and the bottommost channel layer 208b, the middle inner spacer feature 216m is disposed between the bottommost channel layer 208b and the middle channel layer 208m, and the topmost inner spacer feature 216t is disposed between the middle channel layer 208m and the topmost channel layer 208t. The inner spacer feature(s) 216b, 216m, and 216t may be individually or collectively referred to as inner spacer feature(s) 216. It is understood that the number of inner spacer features 216 is a function of the number of sacrificial layers, and the semiconductor structure 200 may include any suitable number of inner spacer features.

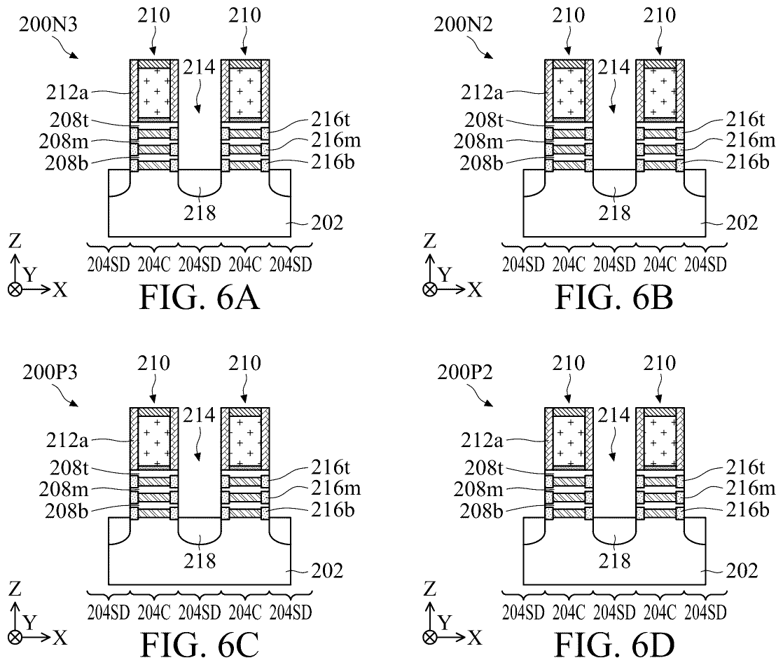

Referring now to FIGS. 1 and 6A-6D, method 100 includes a block 108 where first semiconductor layers 218 are formed in the source/drain openings 214. In the present embodiments, after forming the inner spacer features 216, the first semiconductor layers 218 are formed in the source/drain openings 214 by, for example, using an epitaxial process. Each of the first semiconductor layers 218 may be undoped or not intentionally doped. In some embodiments, the first semiconductor layers 218 may include undoped silicon (Si), undoped germanium (Ge), undoped silicon germanium (SiGe), or other suitable materials. In an embodiment, the first semiconductor layers 218 in the device regions 200N3, 200N2, 200P3, and 200P2 are formed simultaneously by a common epitaxial process and include undoped silicon (Si).

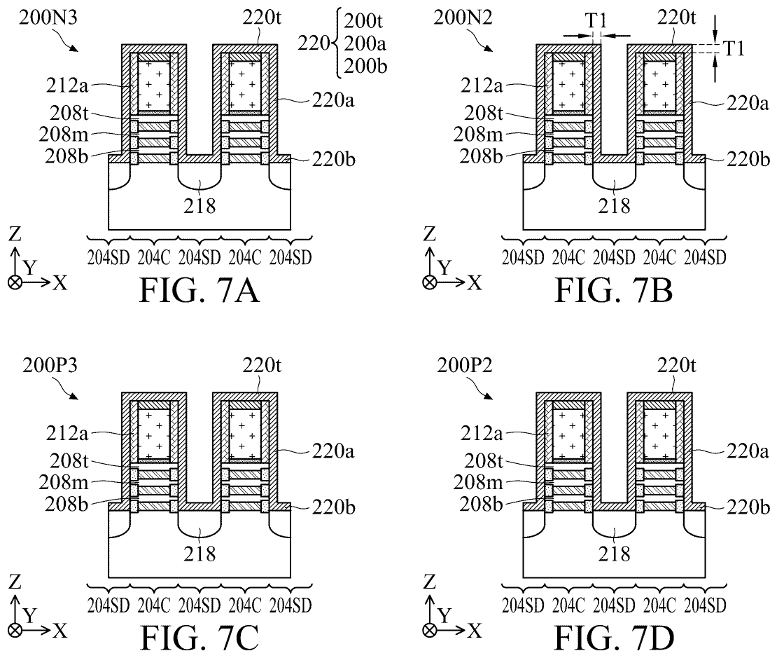

Referring now to FIGS. 1 and 7A-7D, method 100 includes a block 110 where a first dielectric layer 220 is conformally deposited over the semiconductor structure 200. The first dielectric layer 220 may include silicon nitride, silicon carbonitride, silicon oxycarbide, silicon oxycarbonitride, other suitable materials, or combinations thereof. In the present embodiments, the first dielectric layer 220 is conformally deposited over the semiconductor structure 200, including in the source/drain openings 214, by any suitable method, such as CVD, ALD, physical vapor deposition (PVD), other suitable methods, or combinations thereof. The term “conformally” may be used herein for ease of description of a layer having substantially uniform thickness over various regions of the semiconductor structure 200. The first dielectric layer 220 has a deposition thickness T1. As illustrated in FIGS. 7A-7D, the first dielectric layer 220 partially fills the source/drain openings 214. For ease of description, the portion of the first dielectric layer 220 that is in direct contact with the first semiconductor layer 218 while not in direct contact with the inner spacer features 216 or the channel layers 208 is referred to as a horizontal portion 220b; the portion of the first dielectric layer 220 that is in direct contact with the inner spacer features 216, the channel layers 208, and the gate spacers 212a is referred to as a vertical portion 220a; and the portion of the first dielectric layer 220 that is formed over the dummy gate stack 210 is referred to as a top portion 220t.

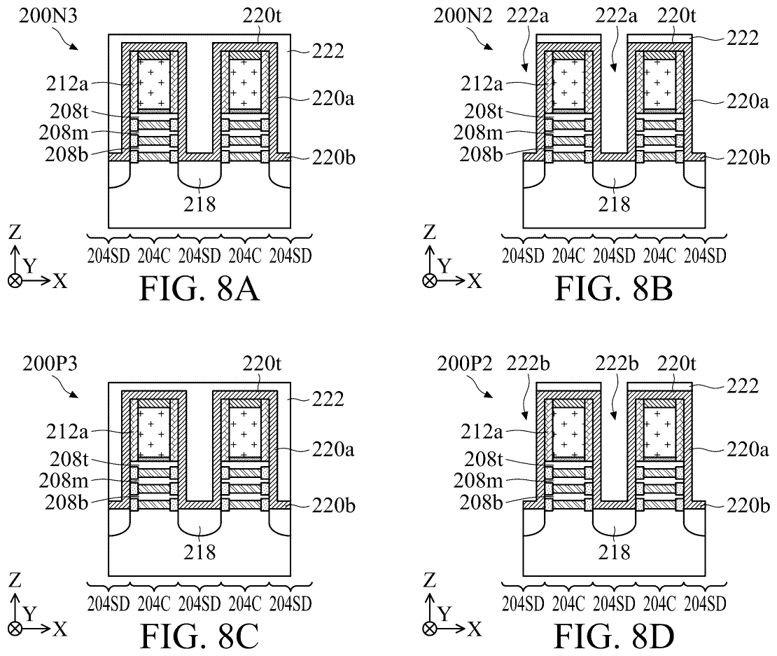

Referring now to FIGS. 1 and 8A-8D, method 100 includes a block 112 where a patterned mask layer 222 is formed over the semiconductor structure 200. The patterned mask layer 222 may include a patterned photoresist layer or a combination of a patterned hard mask layer and a patterned photoresist layer formed on the patterned hard mask layer. In an example process, a photoresist layer is deposited over the semiconductor structure 200 using spin-on coating or a suitable process. The photoresist layer is patterned using photolithography process to form the patterned mask layer 222. In the present embodiment, the patterned mask layer 222 has first openings 222a (shown in FIG. 8B) exposing the horizontal portions 220b of the first dielectric layer 220 in the second n-type device region 200N2 and second openings 222b (shown in FIG. 8D) exposing horizontal portions 220b of the first dielectric layer 220 in the second p-type device region 200P2. The patterned mask layer 222 covers other portions of the first dielectric layer 220 (e.g., portions of the first dielectric layer 220 formed in the first n-type device region 200N3 and the first p-type device region 200P3) in the semiconductor structure 200.

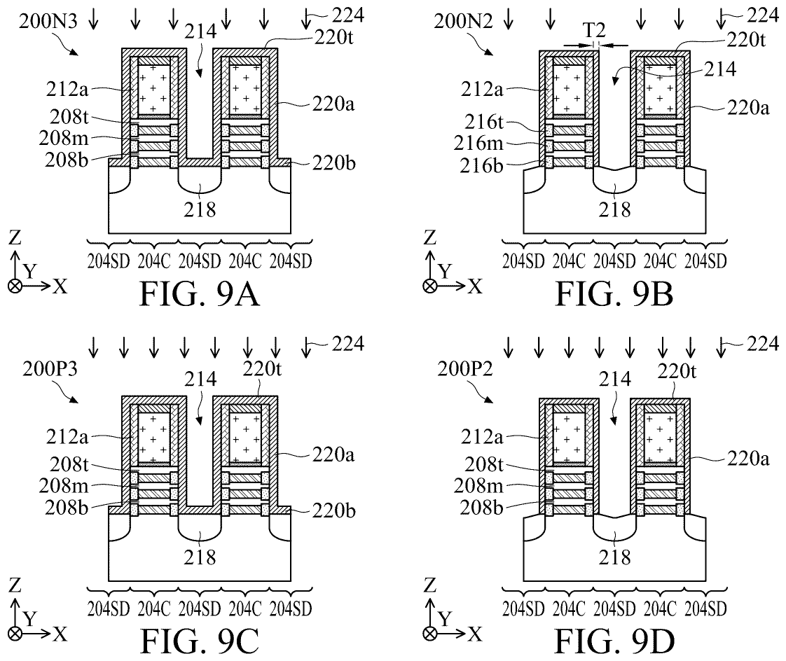

Referring now to FIGS. 1 and 9A-9D, method 100 includes a block 114 where a first etching process 224 is performed to etch the first dielectric layer 220. While using the patterned mask layer 222 as an etch mask, the first etching process 224 is performed to etch the first dielectric layer 220 to remove the horizontal portions 220b of the first dielectric layer 220 exposed by the first openings 222a and the horizontal portions 220b of the first dielectric layer 220 exposed by the second openings 222b. In an embodiment, the first etching process 224 is an anisotropic etching process. The patterned mask layer 222 may be selectively removed after the performing of the first etching process 224. As depicted in FIGS. 9A-9D, the performing of the first etching process 224 removes the horizontal portions 220b of the first dielectric layer 220 in the second n-type device region 200N2 and the horizontal portions 220b of the first dielectric layer 220 in the second p-type device region 200P2. As a result, in the second n-type device region 200N2 and the second p-type device region 200P2, portions of top surfaces of the first semiconductor layers 218 covered by the horizontal portions 220b of the first dielectric layer 220 are now exposed in the source/drain openings 214. Top surfaces of the first semiconductor layers 218 in the first n-type device region 200N3 and the first p-type device region 200P3 are still covered by the first dielectric layer 220. In some embodiments, the performing of the first etching process 224 may also reduce the thickness of the vertical portions 220a of the first dielectric layer 220 in the second n-type device region 200N2 and the second p-type device region 200P2. After the performing of the first etching process 224, the vertical portions 220a of the first dielectric layer 220 in the second n-type device region 200N2 and the second p-type device region 200P2 has a thickness T2 (shown in FIG. 9B) that is less than the deposition thickness T1. In some embodiments, the thickness T2 is in a range between about 1 nm and 4 nm. It is noted that, the vertical portion 220a in the second n-type device region 200N2 and the second p-type device region 200P2 is still in direct contact with a portion of the top surface of the first semiconductor layer 218.

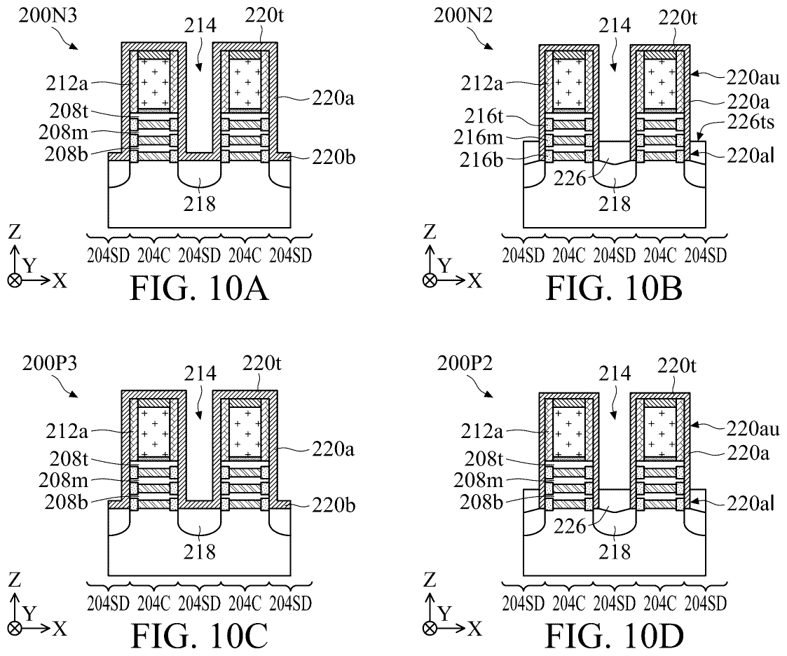

Referring now to FIGS. 1 and 10A-10D, method 100 includes a block 116 where second semiconductor layers 226 are formed on the first semiconductor layers 218 in the second n-type device region 200N2 and the second p-type device region 200P2. After partially exposing the top surfaces of the first semiconductor layers 218 in the second n-type device region 200N2 and the second p-type device region 200P2, the second semiconductor layers 226 are formed on the first semiconductor layers 218. In an embodiment, the second semiconductor layers 226 are formed using an epitaxial growth process and thus are selectively formed on the first semiconductor layers 218 in the second n-type device region 200N2 and the second p-type device region 200P2 from the bottom up (i.e., along the Z direction) without being grown in the first n-type device region 200N3 and the first p-type device region 200P3. Each of the second semiconductor layers 226 may be undoped or not intentionally doped. In some embodiments, the second semiconductor layers 226 may include undoped silicon (Si), undoped germanium (Ge), undoped silicon germanium (SiGe), or other suitable materials. In an embodiment, the second semiconductor layers 226 in the second n-type device region 200N2 and the second p-type device region 200P2 are formed simultaneously and include undoped silicon (Si). In this present embodiment, top surfaces 226ts of the second semiconductor layers 226 are at least coplanar with a bottom surface of the middle inner spacer feature 216m and is below or coplanar with a top surface of the middle inner spacer feature 216m. For ease of description, in the second n-type device region 200N2 and the second p-type device region 200P2, the part of the vertical portion 220a that is in direct contact with the second semiconductor layer 226 is referred to as a lower portion 220al of the first dielectric layer 220, and the part of the vertical portion 220a that is not in direct contact with the second semiconductor layer 226 is referred to as an upper portion 220au of the first dielectric layer 220. As depicted in FIGS. 10B and 10D, the upper portions 220au of the first dielectric layer 220 in the second n-type device region 200N2 and the second p-type device region 200P2 are exposed in the source/drain openings 214.

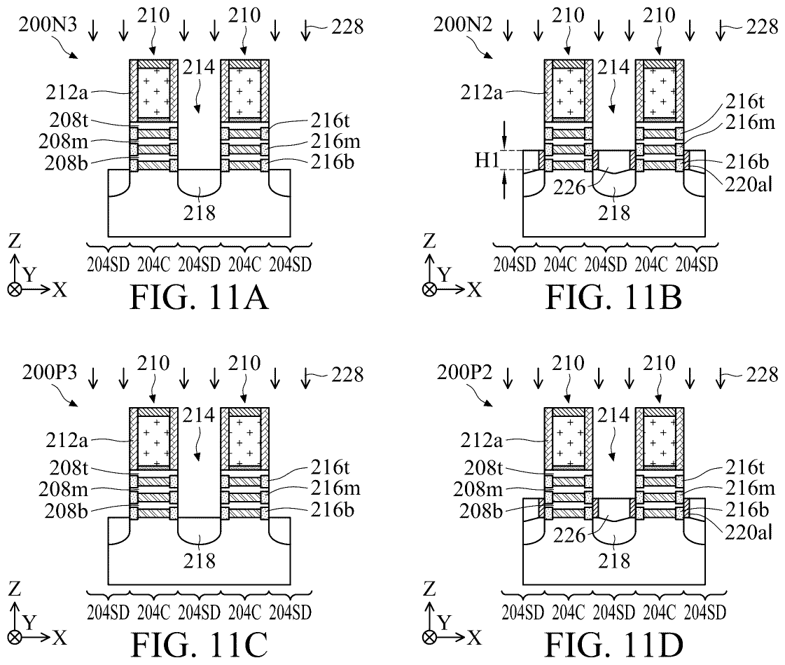

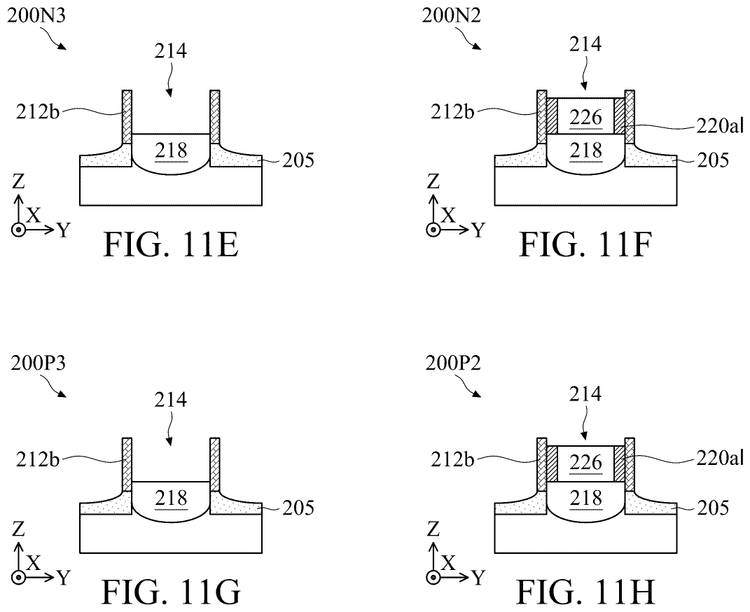

Referring now to FIGS. 1 and 11A-11H, method 100 includes a block 118 where a second etching process 228 is performed to isotropically etch the first dielectric layer 220. After forming the second semiconductor layers 226 in the second n-type device region 200N2 and the second p-type device region 200P2, the second etching process 228 is applied to the semiconductor structure 200. In an embodiment, the second etching process 228 is an isotropic etching process. The performing of the second etching process 228 removes portions of the first dielectric layer 220 not covered/protected by the second semiconductor layers 226, such that the lower portions 220al of the first dielectric layer 220 surround the second semiconductor layers 226 in the second n-type device region 200N2 and the second p-type device region 200P2. The lower portions 220al of the first dielectric layer 220 after the performing of the second etching process 228 may be referred to as sidewall dielectric layers 220al. As depicted herein, the sidewall dielectric layer 220al provides isolation between the bottommost channel layer 208b and the second semiconductor layer 226. In this embodiment, to reduce the number of channel layers that are electrically coupled to source/drain features in the second n-type device region 200N2 and the second p-type device region 200P2, a top surface of the sidewall dielectric layer 220al is above or coplanar with the bottom surface of the middle inner spacer feature 216m and is below or coplanar with the top surface of the middle inner spacer feature 216m. A height H1 of the sidewall dielectric layer 220al may be in a range between about 10 nm and about 20 nm. In the present embodiments, the second etching process 228 selectively etches the first dielectric layer 220 without removing, or substantially removing, portions of the second semiconductor layers 226 and the channel layers 208. As depicted in FIGS. 11A, 11C, 11E and 11G, after the performing of the second etching process 228, top surfaces of the first semiconductor layers 218 in the first n-type device region 200N3 and the first p-type device region 200P3 are exposed in the source/drain openings 214.

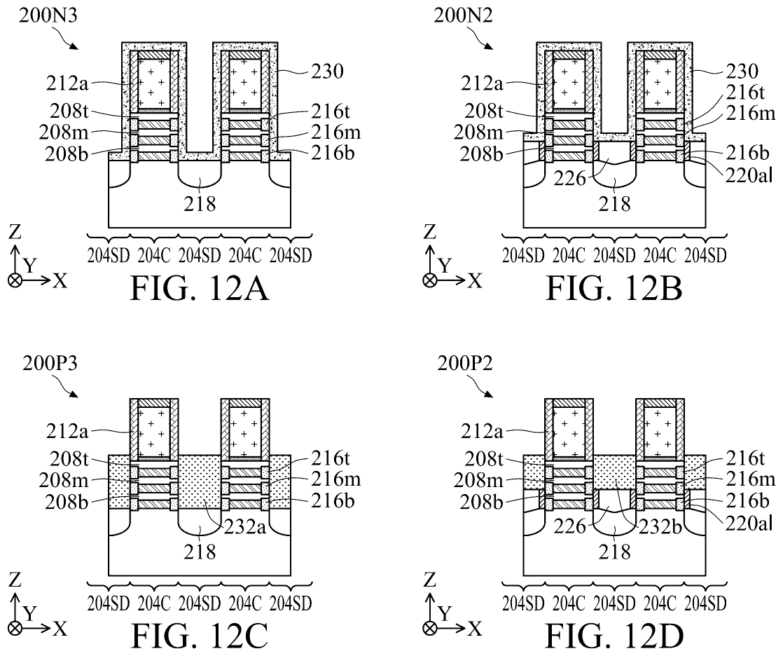

Referring now to FIGS. 1 and 12A-12D, method 100 includes a block 120 where p-type source/drain features 232a and 232b are formed in the source/drain openings 214 in the first and second p-type device regions 200P3 and 200P2, respectively. Source/drain feature(s) may refer to a source or a drain, individually or collectively dependent upon the context. After etching the first dielectric layer 220 to form the sidewall dielectric layers 220al in the second n-type device region 200N2 and the second p-type device region 200P2 and expose top surfaces of the first semiconductor layers 218 in the first n-type device region 200N3 and the first p-type device region 200P3, as depicted in FIGS. 12A-12D, a patterned mask layer 230 is formed over the semiconductor structure 200. The patterned mask layer 230 covers the first and second n-type device region 200N3 and 200N2 while the first and second p-type device region 200P3 and 200P2 are not covered. An epitaxial growth process, such as vapor phase epitaxy (VPE), ultrahigh vacuum chemical vapor deposition (UHV-CVD), molecular-beam epitaxy (MBE), and/or other suitable processes, is then performed to form p-type source/drain features 232a and 232b in the first and second p-type device regions 200P3 and 200P2, respectively. Since the first semiconductor layers 218 are exposed by source/drain openings 214 in the first p-type device region 200P1 and the second semiconductor layers 226 are exposed by source/drain openings 214 in the second p-type device region 200P2, the p-type source/drain features 232a and 232b are allowed to grow from the bottom up (i.e., along the Z direction) to provide satisfactory strain performance. Exemplary p-type source/drain features 232a and 232b may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the p-type source/drain features 232a and 232b may include multiple semiconductor layers with different doping concentrations.

In the first p-type device region 200P3, the p-type source/drain features 232a are coupled to all of the channel layers (i.e., the channel layers 208b, 208m, and 208t) of the channel regions 204C. As depicted in the cross-sectional view represented by FIG. 12C, an entirety of a bottom surface of the p-type source/drain feature 232a is in direct contact with the first semiconductor layer 218, and the p-type source/drain feature 232a is in direct contact with all channel layers (i.e., the channel layers 208b, 208m, and 208t) of the channel regions 204C and the inner spacer features 216b, 216m, 216t.

In the second p-type device region 200P2, the p-type source/drain features 232b are coupled to an upper portion (e.g., channel layers 208m and 208t) of the channel regions 204C and is isolated from a bottom portion (e.g., the bottommost channel layer 208b) by the sidewall dielectric layer 220al. As depicted in the cross-sectional view represented by FIG. 12D, a bottom surface of the p-type source/drain feature 232b is in direct contact with a top surface of the second semiconductor layer 226 and a top surface of the sidewall dielectric layer 220al. That is, the bottom surface of the p-type source/drain feature 232b is above the bottom surface of the p-type source/drain feature 232a. In some embodiments, a volume of the p-type source/drain feature 232a may be greater than a volume of the p-type source/drain feature 232b. After forming the p-type source/drain features 232a and 232b, the patterned mask layer 230 may be selectively removed.

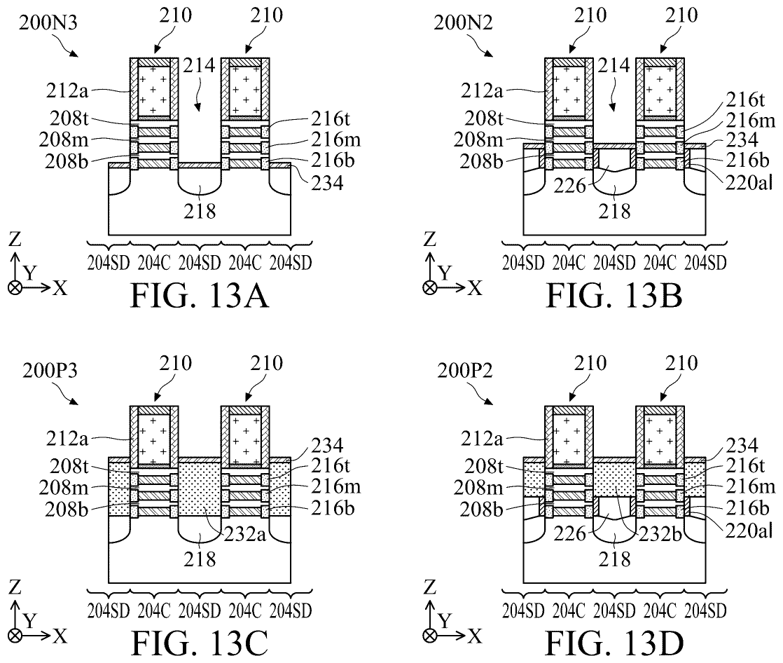

Referring now to FIGS. 1 and 13A-13D, method 100 includes a block 122 where second dielectric layers 234 are formed over the semiconductor structure 200. In the present embodiments, the second dielectric layers 234 are formed on top surfaces of the first semiconductor layers 218 in the first n-type device region 200N3, on the top surfaces of sidewall dielectric layers 220al and second semiconductor layers 226 in the second n-type device region 200N2, on the top surfaces of the p-type source/drain features 232a in the first p-type device region 200P3, and on the top surfaces of the p-type source/drain features 232b in the second p-type device region 200P2.

In an example process, to form the second dielectric layers 234, an insulation layer is first deposited over the semiconductor structure 200 by using a physical vaper deposition (PVD) process. The insulation layer may include silicon nitride, silicon carbonitride, silicon oxycarbide, silicon oxycarbonitride, combination thereof, or other suitable materials. Due to the properties of the PVD process, portions of the insulation layer formed on top or planar surfaces are thicker than portions of the insulation layer formed on sidewall surfaces. Then, portions of the insulation layer that are formed on the top surfaces of the gate spacers 212a, top surfaces of the dummy gate stacks 210, and sidewall surfaces of features (e.g., sidewall surfaces of the gate spacers 212a, sidewall surfaces of exposed channel regions 204C, and sidewall surfaces of inner spacer features 216) are removed by a combination of planarization, deposition, lithography and/or etching processes, thereby leaving bottom portions of the insulation layer in the source/drain openings 214 in the first and second n-type device regions 200N3 and 200N2 and bottom portions of the insulation layer on the p-type source/drain features 232a and 232b in the first and second p-type device regions 200P3 and 200P2. The bottom portions of the insulation layer are referred to as the second dielectric layers 234.

The second dielectric layer 234 in the first n-type device region 200N3 is formed in the source/drain opening 214 and is in direct contact with the first semiconductor layer 218. A bottom surface of the second dielectric layer 234 in the first n-type device region 200N3 is below or coplanar with a top surface of the bottommost inner spacer feature 216b such that the n-type source/drain feature in the first n-type device region 200N3 will be electrically coupled to all channel layers in the channel region 204C.

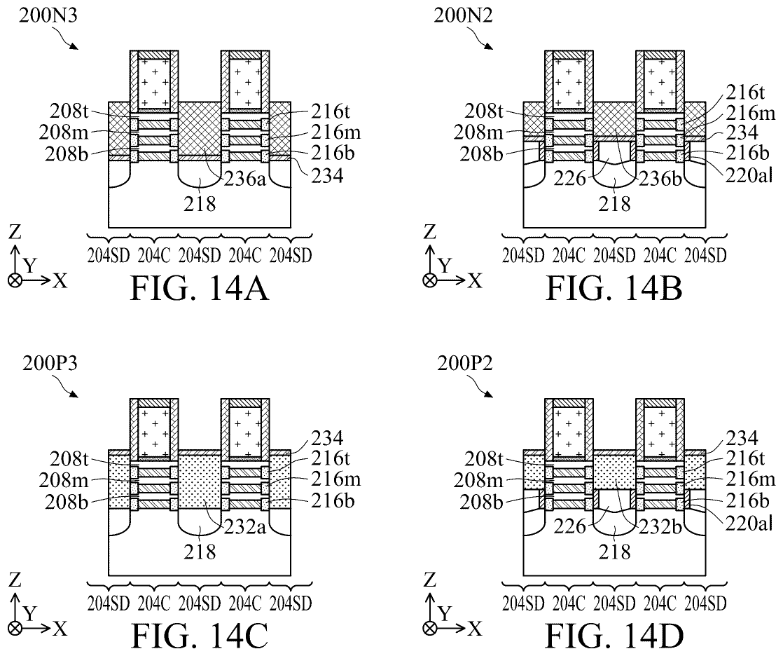

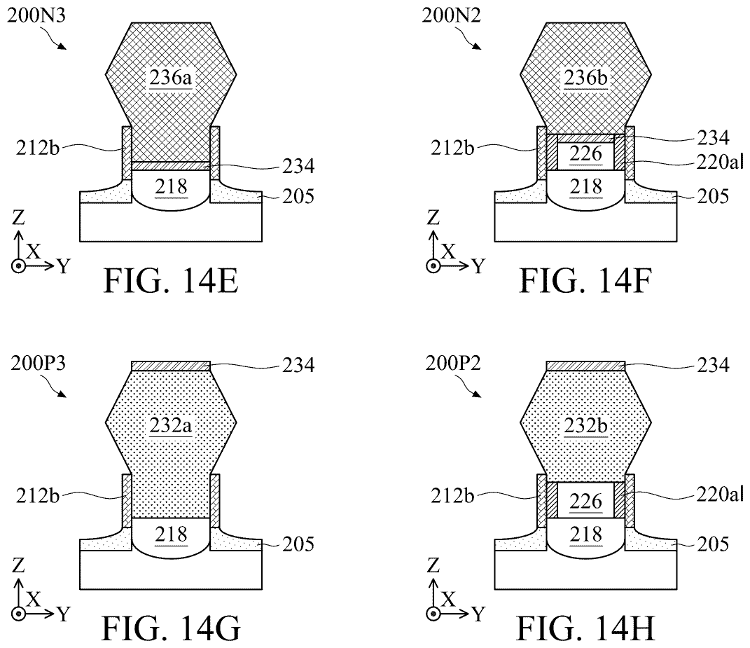

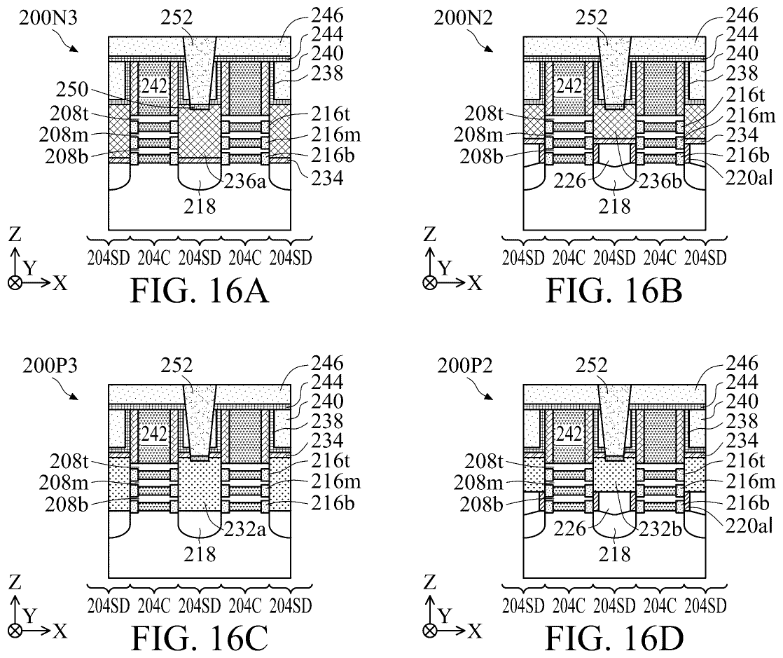

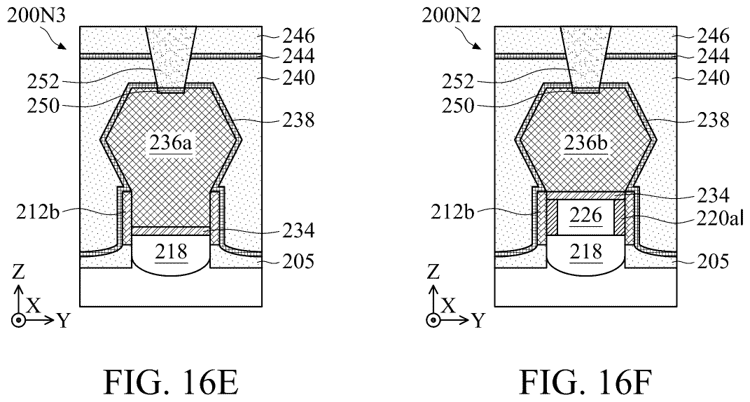

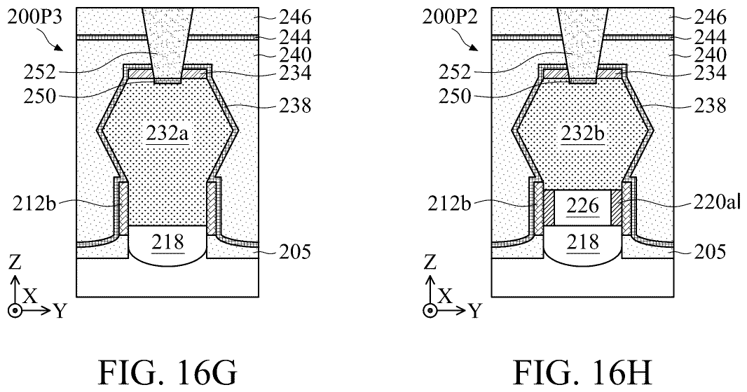

The second dielectric layer 234 in the second n-type device region 200N2 is formed in the source/drain opening 214 and is in direct contact with the sidewall dielectric layer 220al and the second semiconductor layer 226. In this present embodiments, a bottom surface of the second dielectric layer 234 in the second n-type device region 200N2 is below or coplanar with a top surface of the middle inner spacer feature 216m. The formation of the second dielectric layers 234 in the first and second n-type device regions 200N3 and 200N2 will substantially suppress and/or eliminate any parasitic transistor formed between the metal gate structures 242 (shown in FIGS. 16A-16D), n-type source/drain features 236a/236b (shown in FIGS. 14A-14B), and underlying mesa structure(s) 202t, thereby reducing and/or blocking leakage current through the mesa structure(s) 202t in the first and second n-type device regions 200N3 and 200N2. In some implementations, when viewed from the X direction, the second dielectric layers 234 may also be formed on top surfaces of the STI features 205.

Referring now to FIGS. 1 and 14A-14H, method 100 includes a block 124 where n-type source/drain features 236a and 236b are formed in the source/drain openings 214 in the first and second n-type device regions 200N3 and 200N2, respectively. Source/drain feature(s) may refer to a source or a drain, individually or collectively dependent upon the context. After forming the second dielectric layers 234, an epitaxial growth process, such as vapor phase epitaxy (VPE), ultrahigh vacuum chemical vapor deposition (UHV-CVD), molecular-beam epitaxy (MBE), and/or other suitable processes, is then performed to form n-type source/drain features 236a and 236b in the first and second n-type device regions 200N3 and 200N2, respectively. Exemplary n-type source/drain features 236a and 236b may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. In some embodiments, each of the n-type source/drain features 236a and 236b may include multiple semiconductor layers with different doping concentrations.

In the first n-type device region 200N3, the n-type source/drain feature 236a is coupled to and in direct contact with all of the channel layers (i.e., the channel layers 208b, 208m, and 208t) of the channel regions 204C. As depicted in the cross-sectional view represented by FIG. 14A, an entirety of a bottom surface of the n-type source/drain feature 236a is in direct contact with the second dielectric layer 234.

In the second n-type device region 200N2, the n-type source/drain feature 236b is coupled to the upper portion (e.g., channel layers 208m and 208t) of the channel regions 204C and is isolated from the bottom portion (e.g., bottommost channel layer 208b) by the sidewall dielectric layer 220al. As depicted in the cross-sectional view represented by FIG. 14B, an entirety of a bottom surface of the n-type source/drain feature 236b is in direct contact with the second dielectric layer 234. The formation of the second dielectric layers 234 in the first and second n-type device regions 200N3 and 200N2 blocks the conductive path between n-type source/drain features 236a/236b and underlying mesa structure(s) 202t. The bottom surface of the n-type source/drain feature 236b is above the bottom surface of the n-type source/drain feature 236a. In some embodiments, a volume of the n-type source/drain feature 236a may be greater than a volume of the n-type source/drain feature 236b.

Referring now to FIGS. 1 and 15A-15D, method 100 includes a block 126 where dummy gate stacks 210 and sacrificial layers 206 are replaced with gate structures 242. A contact etch stop layer (CESL) 238 and a first interlayer dielectric (ILD) layer 240 are deposited over the semiconductor structure 200. The CESL 238 may include silicon nitride, silicon oxynitride, and/or other suitable materials and may be formed by ALD, plasma-enhanced chemical vapor deposition (PECVD) process and/or other suitable deposition or oxidation processes. The first ILD layer 240 is deposited by a PECVD process or other suitable deposition technique over the semiconductor structure 200 after the deposition of the CESL 238. The first ILD layer 240 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the semiconductor structure 200 to remove excess materials to expose top surfaces of the dummy gate electrode layers 210b in the dummy gate stacks 210. A first etching process may be implemented to selectively remove the dummy gate electrode layers 212 and the dummy gate dielectric layers 211 of the dummy gate stacks 210 without substantially removing the gate spacers 212a to form gate trenches. After the removal of the dummy gate stacks 210, the sacrificial layers 206 in the channel regions 204C are selectively removed to release the channel layers 208 as nanostructures (or channel members) 208. The selective removal of the sacrificial layers 206 forms gate openings under the gate trenches.

After the removal of the dummy gate stacks 210 and the sacrificial layers 206, metal gate structures 242 are formed in the gate trenches and gate openings. The formation of the metal gate structure 242 includes forming an interfacial layer to wrap around and over each of the nanostructures 208. The interfacial layer may include silicon oxide or other suitable material. The interfacial layer may be formed using a suitable method, such as atomic layer deposition (ALD), chemical vapor deposition (CVD), thermal oxidation, or other suitable method. In an embodiment, the interfacial layer is formed by thermal oxidation and is thus only formed on surfaces of the nanostructures 208. That is, the interfacial layer does not extend along sidewall surfaces of the gate spacers 212a and does not extend along sidewall surfaces of the inner spacer features 216. In another embodiment, the interfacial layer is formed by ALD and is thus conformally formed on surfaces of the semiconductor structure 200. That is, the interfacial layer also extends along sidewall surfaces of the gate spacers 212a and sidewall surfaces of the inner spacer features 216. After forming the interfacial layer, a dielectric layer is formed over the semiconductor structure 200 to wrap around and over each of the nanostructures 208. In an embodiment, the dielectric layer is deposited conformally over the semiconductor structure 200. The term “conformally” may be used herein for ease of description of a layer having a substantially uniform thickness over various regions. In some embodiments, the dielectric layer is high-k dielectric layer as its dielectric constant is greater than that of silicon dioxide (˜3.9). In some implementations, the dielectric layer may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The dielectric layer and the interfacial layer may be collectively referred to as a gate dielectric layer.

The formation of the metal gate structure 242 also includes forming a gate electrode over the gate dielectric layer. The gate electrode may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). The metal gate structure 242 formed in the first and second p-type device regions 200P3 and 200P2 may include at least a p-type work function layer. The p-type work function layer may include titanium nitride (TiN), tungsten carbonitride (WCN), tantalum nitride (TaN), or molybdenum nitride (MoN). The metal gate structure 242 formed in the first and second n-type device regions 200N3 and 200N2 may include at least an n-type work function layer. The n-type work function layer may include titanium-aluminum based metal, such as titanium aluminum carbon (TiAIC) or titanium aluminum (TiAl). The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode may be formed by ALD, PVD, CVD, e-beam evaporation, or other suitable process. In various embodiments, a planarization process, such as a chemical mechanical polishing (CMP) process, may be performed to remove excess materials over the first ILD layer 240 to provide a substantially planar top surface and facilitate the performing of further processes.

Referring now to FIGS. 1 and 16A-16H, method 100 includes a block 128 where further processes are performed. Such further processes may include forming an etch stop layer 244 and a second ILD layer 246 over the semiconductor structure 200. The etch stop layer 244 may be similar to the contact etch stop layer 238 and the second ILD layer 246 may be similar to the first ILD layer 240 in terms of composition and formation processes. The etch stop layer 244 may indicate an etch stop point for forming gate via openings over the metal gate structures 242. Source/drain contact openings (now filled by silicide layers 250 and source/drain contacts 252) are formed to expose the p-type source/drain features 232a-232b and/or the n-type source/drain feature 236a-236b using a combination of photolithography processes and etch processes. In an example process, a hard mask layer and a photoresist are deposited over the semiconductor structure 200. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form a patterned hard mask layer. The patterned hard mask layer is then applied as an etch mask to etch the second ILD layer 246, the etch stop layer 244, the first ILD layer 240, and the CESL 238 to form source/drain contact openings in the first and second n-type device regions 200N3 and 200N2. The patterned hard mask layer is also applied as an etch mask to etch the second ILD layer 246, the etch stop layer 244, the first ILD layer 240, the CESL 238, and the second dielectric layer 234 to form source/drain contact openings in the first and second p-type device regions 200P3 and 200P2. After forming the source/drain contact openings, silicide layers 250 and source/drain contacts 252 are formed therein. The silicide layers 250 in the first and second n-type device regions 200N3 and 200N2 may include nickel silicide, titanium silicide, tantalum silicide, cobalt silicide, tungsten silicide, or other suitable materials. The silicide layers 250 in the first and second p-type device regions 200P3 and 200P2 may include nickel silicide, nickel germanide, nickel germanosilicide, titanium silicide, titanium germanide, titanium germanosilicide, tantalum silicide, tantalum germanide, tantalum germanosilicide, cobalt silicide, cobalt germanide, cobalt germanosilicide, tungsten silicide, tungsten germanide, and/or tungsten germanosilicide, or other suitable materials. Source/drain contacts 252 are then formed in the source/drain contact openings and on the silicide layers 250. The source/drain contacts 252 may include aluminum (Al), copper (Cu), tungsten (W), cobalt (Co), ruthenium (Ru), or molybdenum (Mo) or other suitable materials and may be formed by any suitable processes. Although not shown, in some embodiments, barrier layers may be formed to extend along sidewall surfaces of the source/drain contacts 252. Such further processes may include forming gate vias and an interconnect structure over the semiconductor structure 200. In some embodiments, the interconnect structure may include multiple intermetal dielectric (IMD) layers and multiple metal lines or contact vias in each of the IMD layers. In some instances, the IMD layers and the first ILD layer 240 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration. Such further processes may include forming an interconnect structure under the back side of the semiconductor structure 200.

In some alternative embodiments, the electrical characterization of the devices in the semiconductor structure 200 may be further adjusted. For example, effective widths of nanostructures 208 along the X direction may be adjusted to, for example, provide improved DC performance. FIG. 17 illustrates a flow chart of a method 300 for forming a semiconductor structure 400/400′, according to one or more aspects of the present disclosure. Referring to FIG. 17, method 300 includes blocks 102, 104, 106, and 108. In this embodiment, the semiconductor structure 200 (including the first and second n-type device regions 200N3 and 200N2 and first and second p-type device regions 200P3 and 200P2) shown in FIGS. 6A-6D may be referred to as a semiconductor structure 400 that includes first and second n-type device regions 400N3 and 400N2 and first and second p-type device regions 400P3 and 400P2.

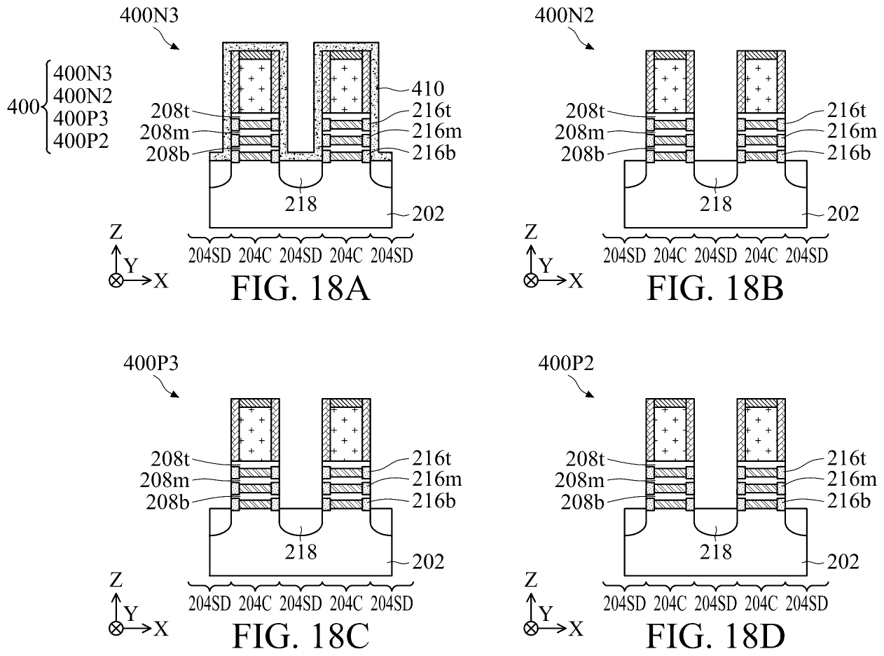

Referring to FIGS. 17 and FIGS. 18A-18D, method 300 also includes a block 310 where a patterned mask layer 410 is formed to cover features in the first n-type device region 400N3. The patterned mask layer 410 may be similar to the patterned mask layer 222 or the patterned mask layer 230. As depicted in FIGS. 18A-18D, the patterned mask layer 410 covers the channel layers (e.g., the channel layers 208b, 208m, and 208t) in the first n-type device region 400N3, while channel layers (e.g., the channel layers 208b, 208m, and 208t) in the second n-type device region 400N2, the first p-type device region 400P3, and the second p-type device region 400P2 are exposed.

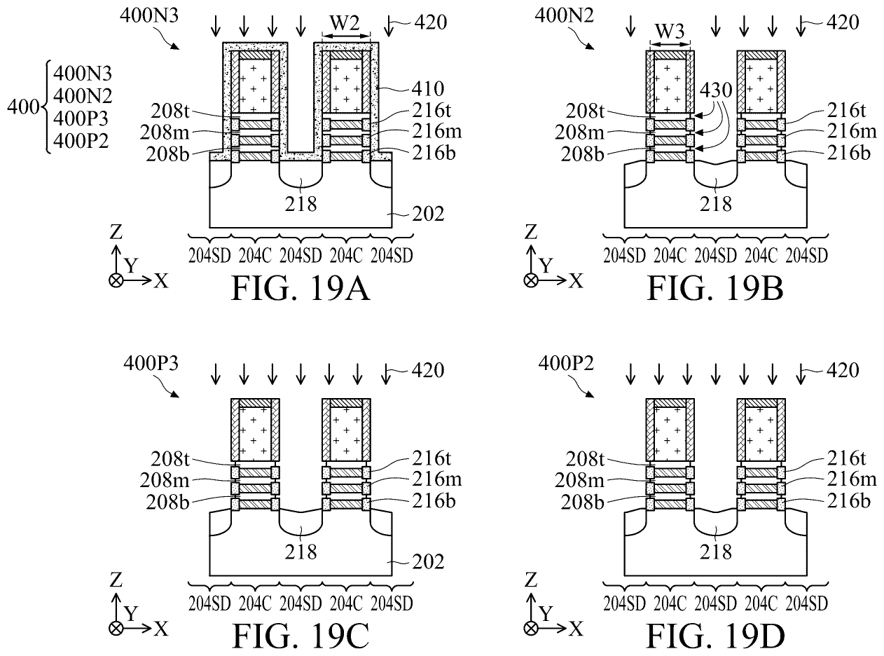

Referring to FIGS. 17 and FIGS. 19A-19D, method 300 also includes a block 320 where an etching process 420 is performed to selectively recess channel layers (e.g., the channel layers 208b, 208m, and 208t) in the second n-type device region 200N2, first and second p-type device region 200P3 and 200P2. While using the patterned mask layer 410 as an etch mask, the etching process 420 is performed to selectively recess channel layers not covered by the patterned mask layer 410. As a result, the channel layers (e.g., the channel layers 208b, 208m, and 208t) in the second n-type device region 400N2, the first p-type device region 400P3, and the second p-type device region 400P2 are recessed and thus have a reduced width W3 along the X direction than a width W2 of channel layers in the first n-type device region 400N3. The recessing of the channel layers (e.g., the channel layers 208b, 208m, and 208t) forms openings 430 in the second n-type device region 400N2, the first p-type device region 400P3, and the second p-type device region 400P2. In some embodiments, the performing of the etching process 420 may also slightly etch the first semiconductor layers 218 in the second n-type device region 400N2, the first p-type device region 400P3, and the second p-type device region 400P2. As depicted in FIGS. 19B-19D, top surfaces of the first semiconductor layers 218 in the second n-type device region 400N2, the first p-type device region 400P3, and the second p-type device region 400P2 curve inward. The patterned mask layer 410 may be selectively removed after the performing of the etching process 420.

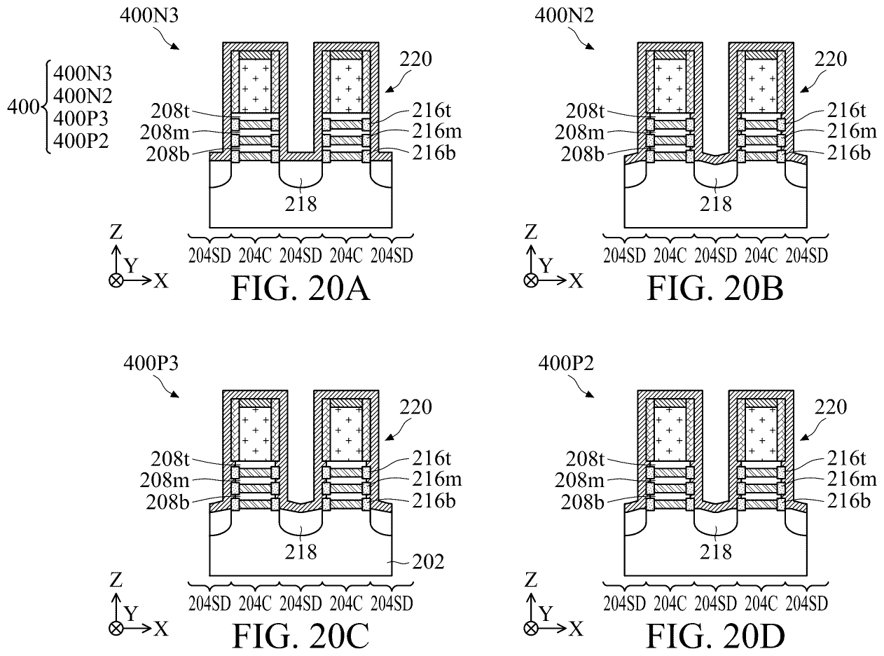

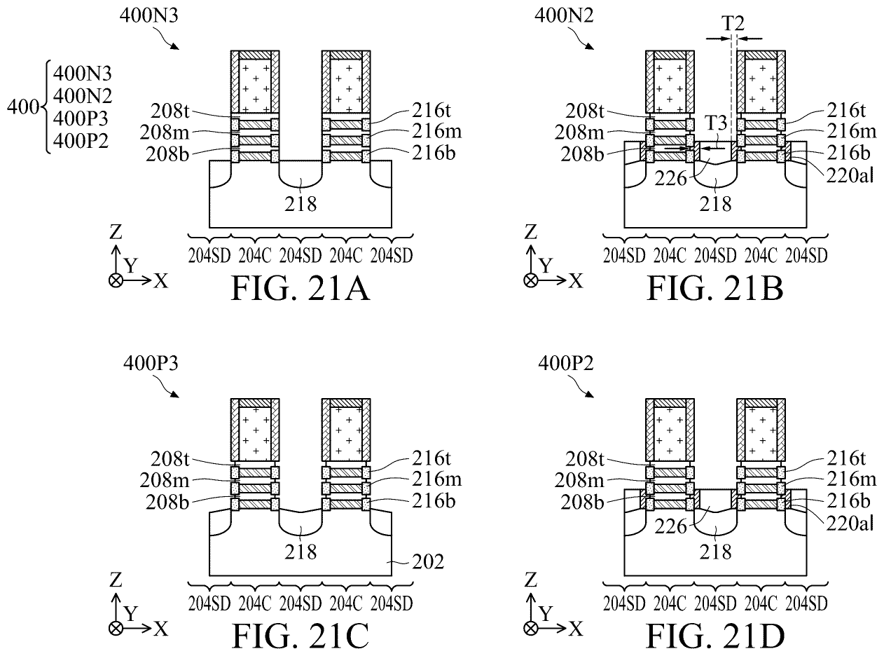

Referring to FIGS. 17 and FIGS. 20A-20D, 21A-21D and 22A-22D, method 300 also includes blocks 110-128. After recessing the channel layers (e.g., the channel layers 208b, 208m, and 208t) in the second n-type device region 400N2, the first p-type device region 400P3, and the second p-type device region 400P2, operations in blocks 110-128 of method 100 are performed to form the semiconductor structure 400. For example, with respect to FIGS. 20A-20D, the first dielectric layer 220 is conformally deposited over the semiconductor structure 400. The first dielectric layer 220 in the semiconductor structure 400 also fills the openings 430. Then, with respect to FIGS. 21A-21D, the second semiconductor layers 226 are formed in the second n-type device region 400N2 and in the second p-type device region 400P2, and portions of the first dielectric layer 220 are removed, thereby leaving the sidewall dielectric layers 220al in the second n-type device region 400N2 and in the second p-type device region 400P2. The sidewall dielectric layers 220al of the semiconductor structure 400 are similar to the sidewall dielectric layers 220al of the semiconductor structure 200, and one of the differences includes that, each of the sidewall dielectric layers 220al of the semiconductor structure 400 also includes a portion that fills the openings 430 and thus is disposed vertically between the bottommost inner spacer feature 216b and the middle inner spacer feature 216m. As a result, the sidewall dielectric layer 220al has a non-uniform thickness from the bottom up. In an embodiment, the top portion and the bottom portion of the sidewall dielectric layer 220al that is in direct contact with sidewall surfaces of the inner spacer features have the thickness T2 in a range between about 1 nm and about 4 nm, and the middle portion of the sidewall dielectric layer 220al that is in direct contact with the bottommost channel layer 208b has a thickness T3 that is in a range between about 3 nm and about 7 nm.

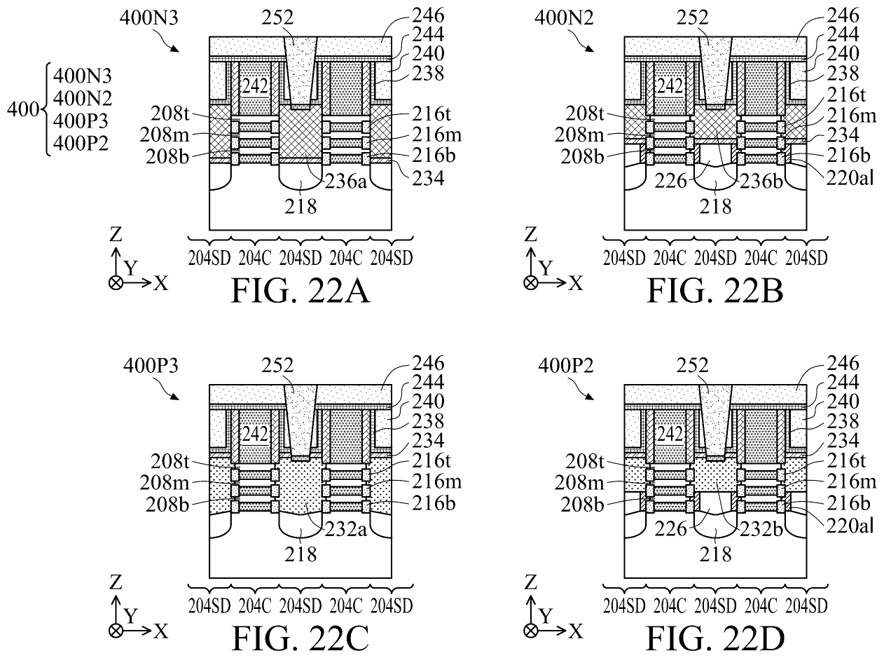

FIGS. 22A-22D depict fragmentary cross-sectional views of the final structure of the semiconductor structure 400. The final structure of the semiconductor structure 400 is similar to the semiconductor structure 200 depicted in FIGS. 16A-16D, and one of the differences between the final structures of the semiconductor structure 400 and semiconductor structure 200 includes the profile of the sidewall dielectric layers 220al. As described above, the sidewall dielectric layers 220al of the semiconductor structure 400 also includes the portion that is disposed vertically between the bottommost inner spacer feature 216b and the middle inner spacer feature 216m. Another difference between the final structures of the semiconductor structure 400 and semiconductor structure 200 includes the different channel widths in the semiconductor structure 400. More specifically, the width W3 (shown in FIG. 19B) of channel layers (e.g., the channel layers 208b, 208m, and 208t) in the second n-type device region 400N2, the first p-type device region 400P3, and the second p-type device region 400P2 are less than width W2 (shown in FIG. 19A) of channel layers (e.g., the channel layers 208b, 208m, and 208t) in the first n-type device region 200N3.

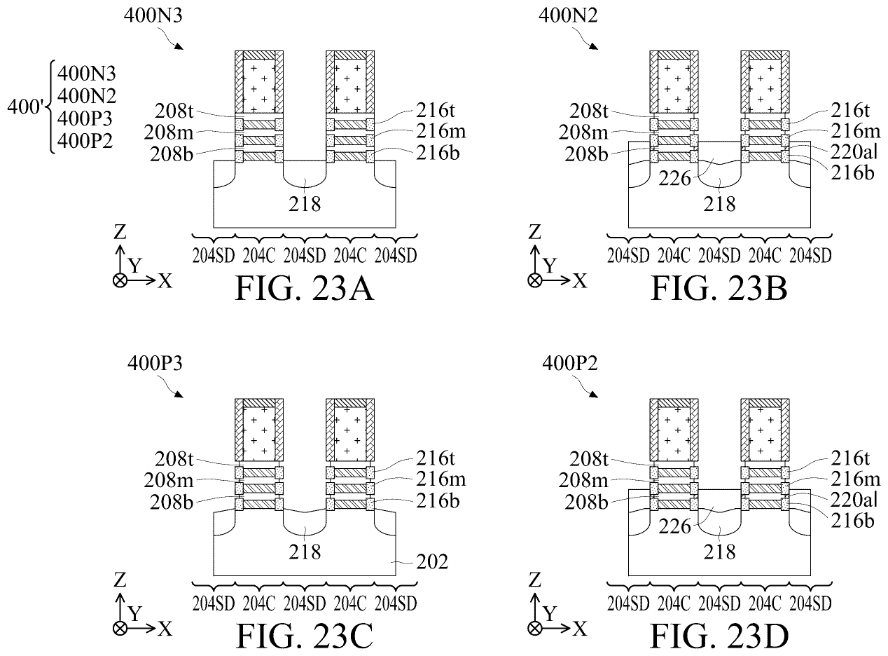

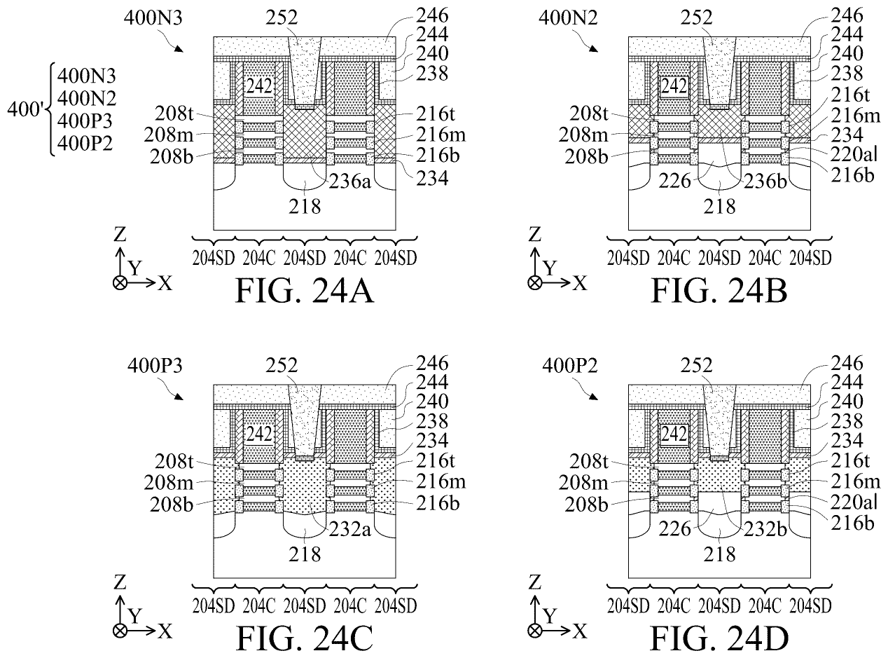

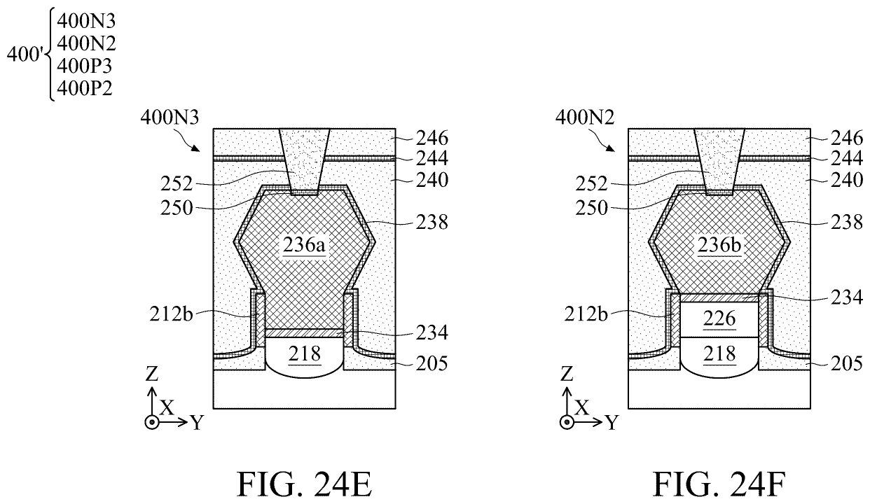

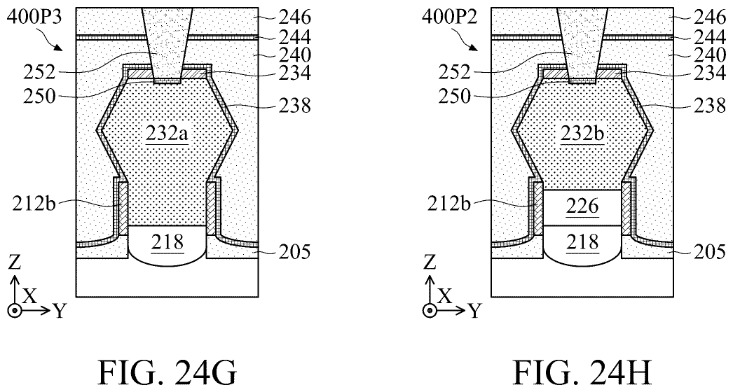

In the above embodiments described with references to FIGS. 21A-21D and 22A-22D, an entirety of the sidewall surface of the second semiconductor layer 226 of the semiconductor structure 400 is lined by the sidewall dielectric layers 220al. The profile of the sidewall dielectric layers 220al may be further adjusted by controlling the etch duration of the first etching process 224 performed in block 114. In an alternative embodiment, the first etching process 224 is performed such that the vertical portion 220a of the first dielectric layer 220 that extends along the sidewall surfaces of the inner spacer features 216b, 216m, and 216t may be substantially removed, leaving the portions of the first dielectric layer 220 formed in the openings 430. As depicted in FIGS. 23A-23D, the sidewall surface of the second semiconductor layer 226 of the semiconductor structure 400′ is in direct contact with the sidewall dielectric layer 220al, the bottommost inner spacer feature 216b, and the inner space feature (e.g., the middle inner space feature 216m in this illustrated example) that is disposed immediately over the bottommost inner spacer feature 216b. FIGS. 24A-24H depict fragmentary cross-sectional views of a final structure of the semiconductor structure 400′. The final structure of the semiconductor structure 400′ depicted in FIGS. 24A-24D is similar to the semiconductor structure 400 depicted in FIGS. 22A-22D, and one of the differences between these the semiconductor structures 400′ and 400 includes the profile of the sidewall dielectric layers 220al and relative positional relationship between the sidewall dielectric layers 220al and its surrounding features, as indicated by FIGS. 24B and FIGS. 24D. FIGS. 24E-24H depict cross-sectional views of the alternative final structure of the semiconductor structure 400′ when viewed from the X direction. In embodiment represented by FIGS. 24E-24H, when viewed from the X direction, an entirety of the sidewall surface of the second semiconductor layer 226 is in direct contact with the fin sidewalls spacers 212b.

In the above embodiments described with reference to FIGS. 17-24H, operations in blocks 310 and 320 (e.g., etching process 420 shown in FIGS. 19A-19D) of method 300 are performed after implementing operations in block 108 (e.g., the formation of the first semiconductor layers 218) and before implementing operations in block 110 (e.g., the deposition of the first dielectric layer 220). In some alternative embodiments, the operations in blocks 310 and 320 are performed after implementing operations in block 118 to form another alternative semiconductor structure 600/600′. FIG. 25 illustrates a flow chart of a method 500 for forming alternative semiconductor structure 600/600′, according to one or more aspects of the present disclosure. Referring to FIG. 25 and FIGS. 11A-11H, method 500 includes blocks 102, 104, 106, 108, 110, 112, 114, 116, and 118. In this embodiment, after performing the operations in block 118, for ease of description, the semiconductor structure 200 shown in FIGS. 11A-11H may be referred to as a semiconductor structure 600 that includes first and second n-type device regions 600N3 and 600N2 and first and second p-type device regions 600P3 and 600P2. As represented by FIGS. 11A-11H, the semiconductor structure 600 includes the sidewall dielectric layer 220al formed in the second n-type device region 600N2 and the second p-type device region 600P2. Detailed description of the sidewall dielectric layer 220al was described above with reference to FIGS. 1-11H and repeated description is omitted for reason of simplicity.

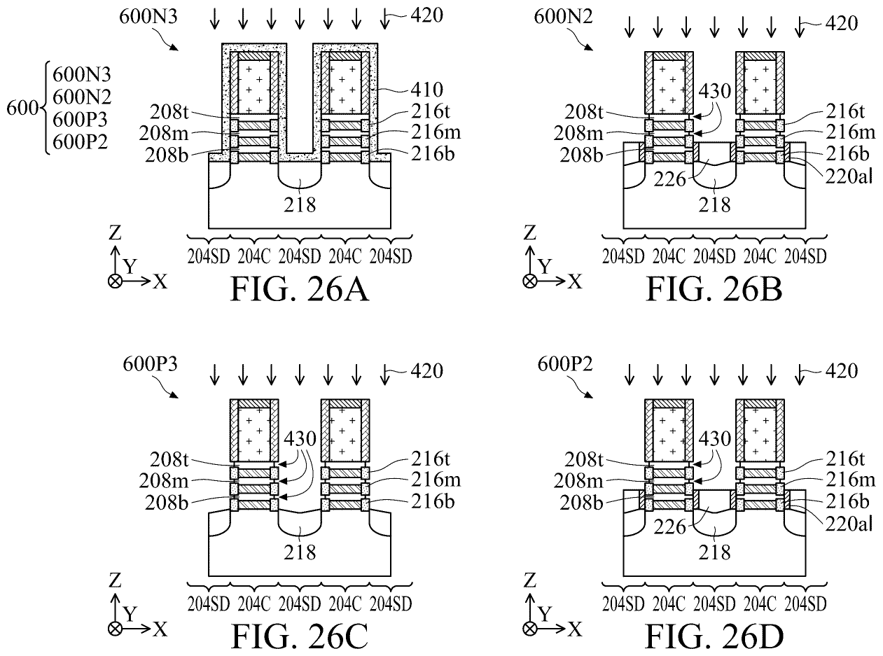

Referring to FIGS. 25 and FIGS. 26A-26D, method 500 also includes a block 310 where the patterned mask layer 410 is formed to cover features in the first n-type device region 600N3. The patterned mask layer 410 may be similar to the patterned mask layer 222 or the patterned mask layer 230. As depicted in FIGS. 18A-18D, the patterned mask layer 410 covers all the channel layers (e.g., the channel layers 208b, 208m, and 208t) in the first n-type device region 600N3. All channel layers (e.g., the channel layers 208b, 208m, and 208t) in the first p-type device region 600P3, channel layers (e.g., the channel layers 208m and 208t) in the second n-type device region 600N2 not covered by the sidewall dielectric layers 220al, and channel layers (e.g., the channel layers 208m and 208t) in the second p-type device region 600P2 not covered by the sidewall dielectric layers 220al are not protected by the patterned mask layer 410.

Still referring to FIGS. 25 and FIGS. 26A-26D, method 500 also includes a block 320 where an etching process 420 is performed to selectively recess channel layers not protected by the patterned mask layer 410. While using the patterned mask layer 410 as an etch mask, the etching process 420 is performed to selectively recess channel layers not covered by the patterned mask layer 410. As a result, the channel layers 208m and 208t in the second n-type device region 600N2, the channel layers 208b, 208m and 208t in the first p-type device region 600P3, and channel layers 208m and 208t in the second p-type device region 600P2 are recessed and thus have reduced widths along the X direction. In addition, in the second n-type device region 600N2 and the second p-type device region 600P2, widths of the channel layers 208m and 208t are less than the width of the respective bottommost channel layer 208b that was not recessed during the performing of the etching process 420. The recess of the channel layers forms openings 430 in the second n-type device region 600N2, the first p-type device region 600P3, and the second p-type device region 600P2. In this embodiment, the performing of the etching process 420 recesses the channel layers without substantially etching the second semiconductor layers 226.

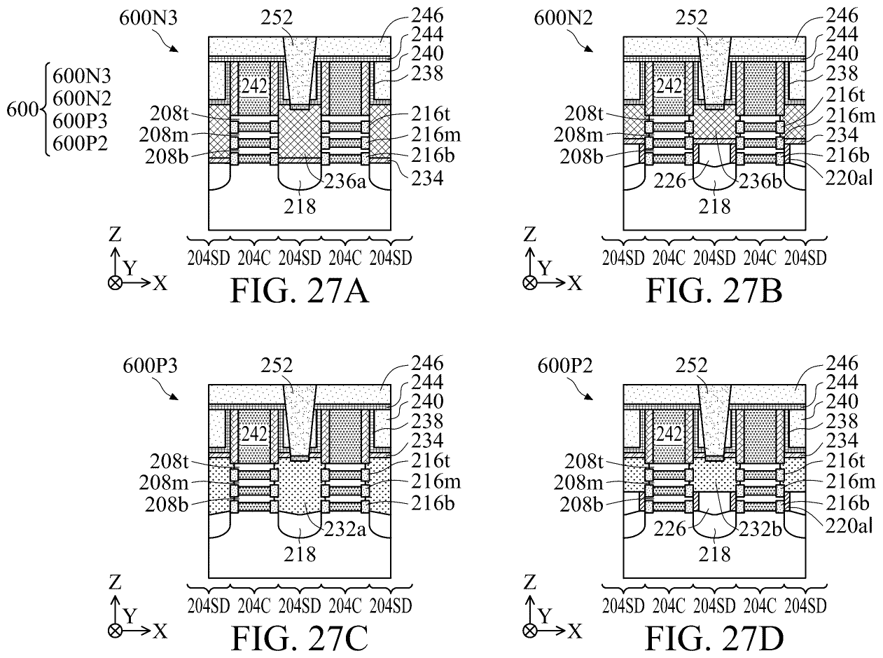

Referring to FIGS. 25 and FIGS. 27A-27D, method 500 also includes blocks 120, 122, 124, 126, and 128. After performing operations in block 320, operations in blocks 120-128 of method 100 are performed to facilitate the formation of the final structure of the semiconductor structure 600. The semiconductor structure 600 is similar to the semiconductor structure 200 represented by FIGS. 16A-16H, and some of the differences between the semiconductor structure 200 and the semiconductor structure 600 include that, in the second n-type device region 600N2 and the second p-type device region 600P2, the channel layers 208t and 208m have reduced widths, and corresponding source/drain features 236b/232b include a first portion that is disposed vertically between the gate spacer 212a and the topmost inner spacer feature 216t and a second portion that is disposed vertically between the topmost inner spacer feature 216t and the middle inner spacer feature 216m; in the first p-type device region 600P3, all channel layers (e.g., the channel layers 208t and 208m, and 208b) have reduced widths, and the p-type source/drain feature 232a includes a first portion that is disposed vertically between the gate spacer 212a and the topmost inner spacer feature 216t, a second portion that is disposed vertically between the topmost inner spacer feature 216t and the middle inner spacer feature 216m, and a third portion that is disposed vertically between the middle inner spacer feature 216m and the bottommost inner spacer feature 216b.

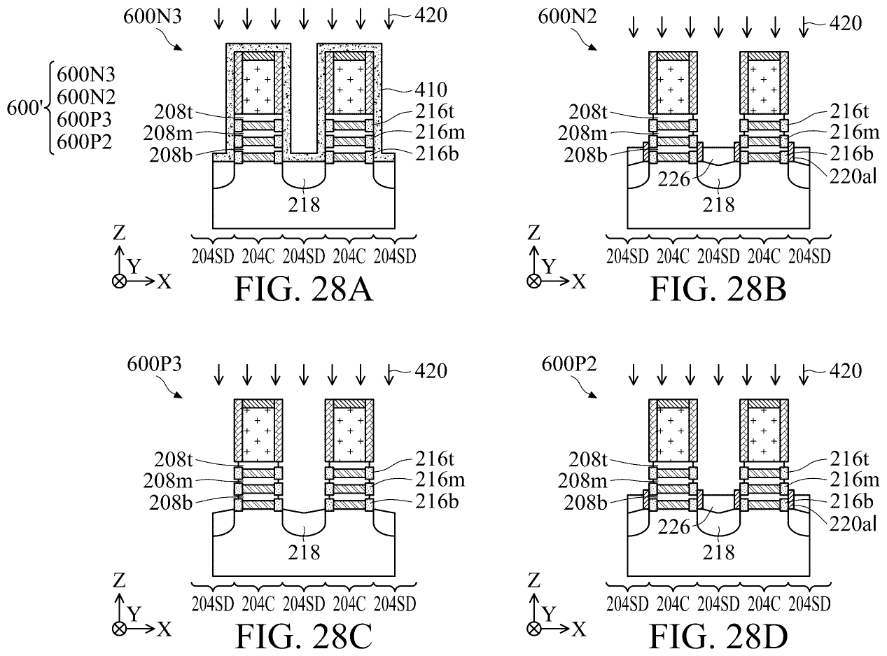

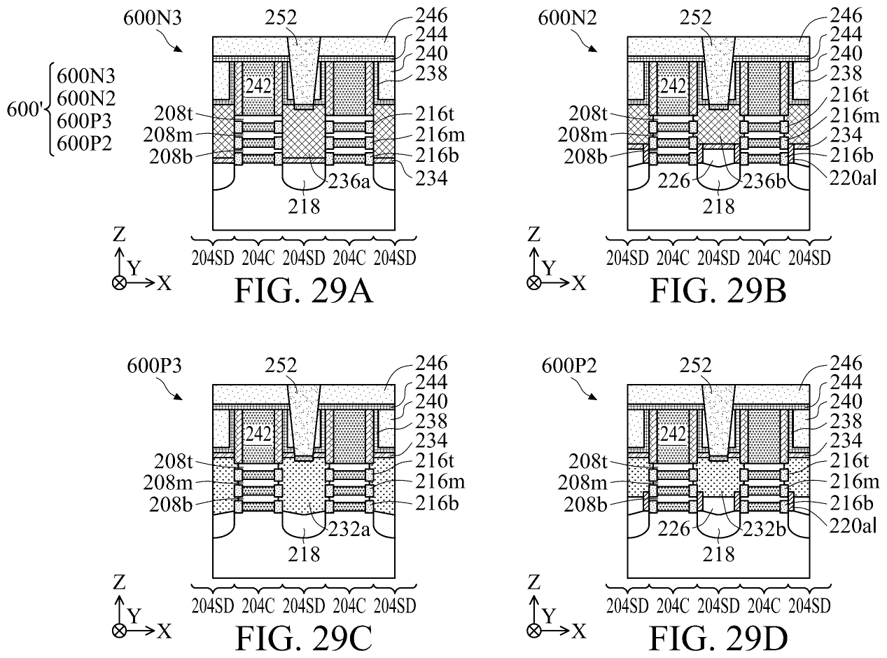

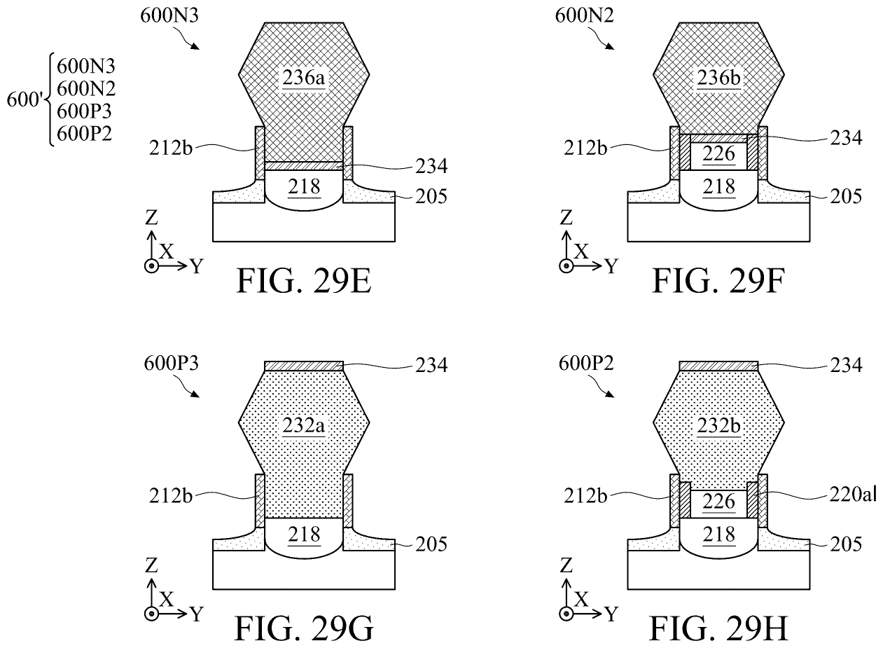

In embodiments represented by FIGS. 26A-27D, the etching process 420 is configured to selectively recess the channel layers without substantially etching the second semiconductor layers 226. In another embodiment represented by FIGS. 28A-28D, the etching process 420 is configured to recess the channel layers and the second semiconductor layers 226. As depicted by FIGS. 28A-28D, after the performing of the etching process 420, the top surface of the second semiconductor layer 226 of the semiconductor structure 600′ is below a top surface of the sidewall dielectric layer 220al. The final structure of this semiconductor structure 600′ is depicted in FIGS. 29A-29H. The semiconductor structure 600′ represented by FIGS. 29A-29H is similar to the semiconductor structure 600 represented by FIGS. 27A-27D, and some of the differences between these two semiconductor structures include that, in the second n-type device region 600N2 of the semiconductor structure 600′, the second dielectric layer 234 is in direct contact with at least a portion of sidewall surface of the sidewall dielectric layer 220al and may be further formed on and in direct contact with the top surface of the sidewall dielectric layer 220al, depending on the thickness of the second dielectric layer 234 and the recessed thickness of the second semiconductor layer 226; in the second p-type device region 600P2 of the semiconductor structure 600′represented by FIG. 29D and FIG. 29H, the p-type source/drain feature 232b includes a bottom portion that extends between and in direct contact with sidewall surfaces of two sidewall dielectric layers 220al formed in the source/drain opening 214. That is, the volume of the p-type source/drain feature 232b of the semiconductor structure 600′ is greater than the volume of the p-type source/drain feature 232b of the semiconductor structure 600. Similarly, the volume of the n-type source/drain feature 236b of the semiconductor structure 600′ is greater than the volume of the n-type source/drain feature 236b of the semiconductor structure 600. Some features in FIGS. 29E-29H are omitted for reason of simplicity.

Although not intended to be limiting, one or more embodiments of the present disclosure provide many benefits to a semiconductor structure and the formation thereof. The present disclosure provides methods and structures that can provide multi-gate devices having a number of semiconductor channel layers selected based on the preferred performance (e.g., low leakage current or high drive current) without sacrificing strain performance of p-type source/drain features of p-type multi-gate devices. The methods may be applied to active regions having same or different configurations (e.g., spacings and widths). By implementing the methods, different regions of a semiconductor structure may be fabricated to GAAs having different performances.

The present disclosure provides for many different embodiments. Semiconductor structures and methods of fabrication thereof are disclosed herein. In one exemplary aspect, the present disclosure is directed to a semiconductor structure. The semiconductor structure includes a first transistor comprising a first gate structure wrapping around a plurality of first nanostructures disposed over a substrate, a first source/drain feature electrically coupled to a topmost nanostructure of the plurality of first nanostructures and isolated from a bottommost nanostructure of the plurality of first nanostructures by a first dielectric layer, and a first semiconductor layer disposed between the substrate and the first source/drain feature, wherein the first source/drain feature is in direct contact with a top surface of the first semiconductor layer.

In some embodiments, the first dielectric layer may extend along a sidewall surface of the first semiconductor layer. In some embodiments, the first transistor may also include a plurality of inner spacer features disposed between two adjacent nanostructures of the plurality of first nanostructures, wherein the first dielectric layer extends along a sidewall surface of a bottommost inner spacer feature of the plurality of inner spacer features. In some embodiments, a portion of the first dielectric layer may be disposed over and in direct contact with a top surface of the bottommost inner spacer feature of the plurality of inner spacer features. In some embodiments, a sidewall surface of the first semiconductor layer may be in direct contact with both the first dielectric layer and the bottommost inner spacer feature of the plurality of inner spacer features. In some embodiments, the first source/drain feature may be a p-type source/drain feature. In some embodiments, the first source/drain feature may be disposed adjacent to the plurality of first nanostructures along a first direction, and a width of the bottommost nanostructure of the plurality of first nanostructures may have a width along the first direction greater than widths of other nanostructures of the plurality of first nanostructures. In some embodiments, a top surface of the first dielectric layer may be above the top surface of the first semiconductor layer. In some embodiments, the semiconductor structure may also include a second transistor comprising a second gate structure wrapping around a plurality of second nanostructures disposed over the substrate, a second source/drain feature electrically coupled to a topmost nanostructure of the plurality of second nanostructures and isolated from a bottommost nanostructure of the plurality of second nanostructures by a second dielectric layer, and a second semiconductor layer adjacent to the second dielectric layer and isolated from the second source/drain feature by a third dielectric layer. In some embodiments, the first dielectric layer and the second dielectric layer may include a same composition and a same thickness. In some embodiments, the second source/drain feature may be an n-type source/drain feature. In some embodiments, the third dielectric layer may be in direct contact with the second source/drain feature, the second dielectric layer, and the second semiconductor layer.

In another exemplary aspect, the present disclosure is directed to a transistor. The transistor includes a gate structure wrapping around a plurality of nanostructures disposed over a substrate, an undoped semiconductor layer in and over the substrate, wherein a top surface of the undoped semiconductor layer is coplanar with or above a top surface of a bottommost nanostructure of the plurality of nanostructures, a dielectric layer disposed between the undoped semiconductor layer and the bottommost nanostructure of the plurality of nanostructures, and a source/drain feature adjacent to the plurality of nanostructures, wherein a bottom surface of the source/drain feature is in direct contact with a top surface of the undoped semiconductor layer.

In some embodiments, the undoped semiconductor layer may also include a first portion embedded in the substrate and a second portion on the substrate, an entirety of a sidewall surface of the second portion of the undoped semiconductor layer may be covered by the dielectric layer. In some embodiments, the transistor may also include a plurality of inner spacer features disposed vertically between two adjacent nanostructures of the plurality of nanostructures, wherein the dielectric layer is disposed between the undoped semiconductor layer and a bottommost inner spacer feature of the plurality of inner spacer features. In some embodiments, the dielectric layer may be in direct contact with the source/drain feature, the undoped semiconductor layer, and the bottommost inner spacer feature of the plurality of inner spacer features.

In yet another exemplary aspect, the present disclosure is directed to a method. The method includes forming a first fin-shaped active region extending from a substrate and comprising a plurality of channel layers interleaved by a plurality of sacrificial layers, forming a first gate stack over a first channel region of the first fin-shaped active region, recessing a first source/drain region of the first fin-shaped active region to form a first source/drain opening, forming a first semiconductor layer in a bottom portion of the first source/drain opening, forming a first dielectric layer extending along a sidewall surface of a middle portion of the first source/drain opening and on the first semiconductor layer, wherein an entirety of a sidewall surface of a bottommost channel layer of the plurality of channel layers is covered by the first dielectric layer, forming a second semiconductor layer on the first semiconductor layer, wherein a sidewall surface of the second semiconductor layer is in direct contact with the first dielectric layer, forming a first source/drain feature on the second semiconductor layer, and replacing the first gate stack and the plurality of sacrificial layers with a gate structure.

In some embodiments, the method may also include selectively etching the sacrificial layers to form inner spacer recesses and forming inner spacer features in the inner spacer recesses. In some embodiments, the first source/drain feature is a p-type source/drain feature and is in direct contact with both the second semiconductor layer and the first dielectric layer. In some embodiments, the forming of the first dielectric layer may also include conformally depositing an insulation layer over the substrate, the insulation layer comprises a vertical portion extending along a sidewall surface of the first source/drain opening and a horizontal portion extending along a top surface of the first semiconductor layer, performing a first etching process to remove the horizontal portion of the insulation layer, and after the forming of the second semiconductor layer, performing a second etching process to remove parts of the vertical portion of the insulation layer not covered by the second semiconductor layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a channel region;
an isolation structure adjacent to the channel region;
a gate structure over the channel region;
a first epitaxial structure interfacing a sidewall of an upper portion of the channel region;
a second epitaxial structure disposed adjacent to a lower portion of the channel region;
an isolation layer sandwiched by the first epitaxial structure and the second epitaxial structure;
an etch stop layer over the isolation structure and the second epitaxial structure; and
a dielectric layer over the etch stop layer, wherein the first epitaxial structure is doped with a dopant, wherein the first epitaxial structure comprises a first layer adjacent the sidewall of the channel region and a second layer away from the sidewall of the channel region, wherein a concentration of the dopant in the first layer is different from a concentration of the dopant in the second layer.

2. The semiconductor device of claim 1, further comprising:
a dielectric liner disposed laterally between the second epitaxial structure and the lower portion of the channel region.

3. The semiconductor device of claim 2, further comprising:
an undoped semiconductor layer disposed under the second epitaxial structure.

4. The semiconductor device of claim 3, wherein the second epitaxial structure is undoped.

5. The semiconductor device of claim 3, wherein the dielectric liner is disposed on the undoped semiconductor layer.

6. The semiconductor device of claim 1, wherein the channel region comprises a plurality of nanostructures.

7. The semiconductor device of claim 6, wherein the isolation layer is disposed over a bottommost nanostructure of the plurality of nanostructures.

8. The semiconductor device of claim 6, wherein a portion of the gate structure wraps around the plurality of nanostructures, and the semiconductor device further comprises a plurality of inner spacers disposed between the portion of the gate structure and the second epitaxial structure and between the portion of the gate structure and the first epitaxial structure.

9. The semiconductor device of claim 8, wherein the second epitaxial structure is physically separated from the plurality of inner spacers.

10. A semiconductor device, comprising:
a substrate;
a semiconductor structure extending lengthwise along a first direction over the substrate and comprising a width along a second direction different from the first direction;
a plurality of nanostructures over the semiconductor structure;
an isolation structure surrounding the semiconductor structure;
an undoped semiconductor feature disposed adjacent to the plurality of nanostructures and comprising an upper portion over the semiconductor structure and a lower portion extended into the semiconductor structure, wherein the upper portion is physically separated from the plurality of nanostructures; and
a source/drain feature disposed over the undoped semiconductor feature, wherein a width of the source/drain feature is greater than a width of the semiconductor structure such that a portion of the source/drain feature overhangs the isolation structure, wherein the source/drain feature comprises a first layer and a second layer, wherein a composition of the first layer is different from a composition of the second layer.

11. The semiconductor device of claim 10, wherein the upper portion has a first width and the lower portion has a second width greater than the first width.

12. The semiconductor device of claim 10, further comprising:
a dielectric layer extending along a sidewall of the upper portion of the undoped semiconductor feature and disposed on the lower portion of the undoped semiconductor feature.

13. The semiconductor device of claim 12, further comprising:
an isolation layer extending along a top surface of the upper portion of the undoped semiconductor feature.

14. The semiconductor device of claim 13, wherein the isolation layer further extends on a top surface of the dielectric layer.

15. The semiconductor device of claim 12, wherein the dielectric layer further extends along a sidewall surface of a bottommost nanostructure of the plurality of nanostructures.

16. The semiconductor device of claim 15, wherein the source/drain feature is an n-type doped source/drain feature.

17. A semiconductor device, comprising:
a substrate;
an active region comprising a channel region and a source/drain region and extending lengthwise along a direction;
an isolation feature disposed over the substrate and adjacent to the active region, wherein a top surface of the isolation feature is non-planar when viewed along the direction;
an epitaxial feature in the source/drain region;
a source/drain feature in the source/drain region and over the epitaxial feature;
a dielectric layer configured to provide isolation between the epitaxial feature and the source/drain feature;
an interlayer dielectric (ILD) layer over the source/drain feature; and
a source/drain contact extending through the ILD layer to electrically couple to the source/drain feature.

18. The semiconductor device of claim 17, further comprising:
an isolation layer configured to provide isolation between the epitaxial feature and the channel region.

19. The semiconductor device of claim 18, wherein the dielectric layer extends on top surfaces of the isolation layer and the epitaxial feature.

20. The semiconductor device of claim 17, wherein the epitaxial feature comprises a first portion embedded in the substrate and a second portion between the first portion and the source/drain feature, wherein a width of the second portion is less than a width of the first portion.
